(19) United States
(12) Patent Application Publication
(10) Pub. No.: US 2026/0045214 A1
(43) Pub. Date: Feb. 12, 2026

(54) DISPLAY DEVICE AND VEHICLE INCLUDING THE SAME

(71) Applicant: Samsung Display Co., LTD., Yongin-si (KR)

(72) Inventors: HYANGYUL KIM, Yongin-si (KR); JAEHONG KIM, Yongin-si (KR); HYUNHO JUNG, Yongin-si (KR); HEESEONG JEONG, Yongin-si (KR)

(73) Assignee: Samsung Display Co., LTD., Yongin-si (KR)

(21) Appl. No.: 19/095,613

(22) Filed: Mar. 31, 2025

(30) Foreign Application Priority Data
Aug. 7, 2024 (KR) 10-2024-0105700

(51) Int. Cl. G09G 3/3233; B60K 35/22; H10K 59/122; H10K 59/80

(52) U.S. Cl. CPC G09G 3/3233; B60K 35/22; H10K 59/122; H10K 59/8792; B60K 2360/1523; G09G 2300/0819; G09G 2300/0842; G09G 2300/0861; G09G 2320/0233; G09G 2320/0242; G09G 2320/0257; G09G 2320/041; G09G 2320/0673; G09G 2330/023; G09G 2354/00; G09G 2360/14; G09G 2380/10

(57) ABSTRACT

A display device includes a display panel divided into a first display area, a second display area, and a peripheral area surrounding the first display area and the second display area, and including a first display panel disposed at a location corresponding to the first display area and a second display panel disposed at a location corresponding to the second display area, and a first light control member disposed in the first display area, the first display panel may include a first substrate and a first pixel defining layer disposed on the first substrate and that defines a pixel, and the second display panel may include a second substrate and a second pixel defining layer disposed on the second substrate and that defines a pixel, the second pixel defining layer is a black pixel defining layer.

### CROSS-REFERENCE TO RELATED APPLICATION(S)

This application claims priority to and benefits of Korean Patent Application No. 10-2024-0105700 under 35 USC § 119, filed on Aug. 7, 2024, in the Korean Intellectual Property Office, the entire contents of which are incorporated herein by reference.

### BACKGROUND

### 1. Technical Field

The disclosure relates to a display device.

### 2. Description of the Related Art

As the demand for display devices expands, the need for display devices that can be used for various purposes is also increasing. In line with this trend, display devices are becoming larger and thinner, and the demand for display devices that provide precise and vivid colors while being larger and thinner is also increasing.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments are directed to a display device with improved visibility and optical characteristics.

However, the above objectives are examples, and the scope of the disclosure is not limited thereto.

Additional aspects will be set forth in part in the description which follows and, in part, will be apparent from the description, or may be learned by practice of the presented embodiments of the disclosure.

According to an aspect of the disclosure, there is provided a display device that may include a display panel divided into a first display area, a second display area, and a peripheral area surrounding the first display area and the second display area, and including a first display panel disposed at a location corresponding to the first display area and a second display panel disposed at a location corresponding to the second display area; and a first light control member disposed in the first display area, wherein the first display panel may include a first substrate and a first pixel defining layer disposed on the first substrate and that defines a pixel, and the second display panel may include a second substrate and a second pixel defining layer disposed on the second substrate and that defines a pixel, wherein the second pixel defining layer may be a black pixel defining layer.

The display device may further include a window disposed on the display panel that covers the first display area and the second display area.

The display device may further include a light-blocking member that overlaps at least a portion of a periphery of the first display area and the second display area.

The display device may further include a light-blocking member that overlaps a boundary between the first display panel and the second display panel.

The first light control member may include a light-absorbing layer that absorbs at least a portion of light emitted from the first display panel or external light.

The first light control member may have a louver structure.

The louver structure may be formed in a direction parallel to a width direction of the display panel.

The second pixel defining layer may absorb at least a portion of external light incident on the second display panel.

The second display panel may further include a second wiring disposed between the substrate and the second pixel defining layer, and external light incident on the second display panel may not reach the second wiring.

A difference between a specular component included_b* (SCI_b*) value of a first reflection color and a specular component included_b* (SCI_b*) value of a second reflection color may be at least 0 and not more than 3, the first reflection color being exhibited by external light reflected on the first display panel, and the second reflection color being exhibited by external light reflected on the second display panel.

The first display panel and the second display panel may include a plurality of pixels disposed on the substrate, wherein the plurality of pixels may include a first pixel, a second pixel, and a third pixel that emit light of different colors, wherein at least two of the first pixel, the second pixel, and the third pixel may have different areas.

The plurality of pixels may be disposed such that pixels disposed in a first direction and pixels disposed in a second direction that is rotated by about 90° from the first direction are disposed in a zigzag pattern.

The plurality of pixels may be disposed diagonally with respect to a width direction of the display panel.

The first pixel defining layer may be a black pixel defining layer.

The display panel may further include a third display area different from the first display area and the second display area, a third display panel disposed at a location corresponding to the third display area, and a third light control member disposed in the third display area.

Each of the first light control member and the third light control member may have a louver structure.

The louver structure of the first light control member and the louver structure of the third light control member may be formed in different directions.

The louver structure of the first light control member and the louver structure of the third light control member may be perpendicular.

The display device may further include a light-blocking member that overlaps a boundary surface of the second display panel and a boundary surface of the third display panel.

The first display panel and the second display panel may be a single integral body.

According to an aspect of the disclosure, there is provided a vehicle that may include a controller that generates a scan input signal, a power module that generates a scan input voltage, and a display device that is partitioned into a display area, in which a pixel circuit is disposed, and a peripheral area disposed outside of the display area and including a pad area, wherein the display device may include a display panel divided into a first display area, a second display area, and a peripheral area surrounding the first display area and the second display area, and including a first display panel disposed at a location corresponding to the first display area and a second display panel disposed at a location corresponding to the second display area, and a first light control member disposed in the first display area, wherein the first display panel may include a first substrate and a first pixel defining layer disposed on the first substrate and that defines a pixel, and the second display panel may include a second substrate and a second pixel defining layer disposed on the second substrate and that defines a pixel, wherein the second pixel defining layer may be a black pixel defining layer.

The electronic device may further comprise a window disposed on the display panel that covers the first display area and the second display area.

The electronic device may further comprise a light-blocking member that overlaps at least a portion of a periphery of the first display area and the second display area.

The electronic device may further comprise a light-blocking member that overlaps a boundary between the first display panel and the second display panel.

The first light control member may include a light-absorbing layer that absorbs at least a portion of light emitted from the first display panel or external light.

The first light control member may have a louver structure.

The electronic device may be at least one of an organic light-emitting display apparatus, an inorganic light-emitting display apparatus, a quantum dot light-emitting display apparatus, display screens of portable electronic apparatus, such as mobile phones, smartphones, tablet personal computers (PCs), mobile communication terminals, electronic notebooks, electronic books, portable multimedia players (PMPs), navigation devices, and ultra mobile PCs (UMPCs), display screens of televisions, notebooks, monitors, advertisement panels, Internet of things (IoT) devices, a portable communication device a smartphone, a computer device, a portable multimedia device, a portable medical device, a camera, a wearable device, and a home appliance.

### BRIEF DESCRIPTION OF THE DRAWINGS

The above and other aspects, features, and advantages of given embodiments will be more apparent from the following description taken in conjunction with the accompanying drawings, in which:

FIG. 1 is a schematic perspective view illustrating a display device according to an embodiment;

FIG. 2 is a schematic cross-sectional view illustrating an example of a cross section taken along line I-I′ of FIG. 1;

FIG. 3 is a schematic plan view illustrating a portion of the display device of FIG. 1;

FIG. 4 is a schematic diagram of an equivalent circuit illustrating an example of one pixel of the display device of FIG. 1;

FIG. 5 is a partial schematic plan view illustrating an example of a pixel arrangement of the display device of FIG. 1;

FIG. 6 is a schematic cross-sectional view illustrating an example of a cross section taken along line II-II′ of FIG. 5;

FIG. 7 is a schematic perspective view illustrating a display device according to an embodiment;

FIG. 8 is a schematic cross-sectional view illustrating an example of a cross section taken along line III-III′ of FIG. 7;

FIG. 9 is a schematic cross-sectional view illustrating an example of a cross section taken along line IV-IV′ of FIG. 7;

FIGS. 10 and 11 are enlarged schematic views illustrating an example of an interior of a first display panel of FIG. 8;

FIGS. 12 and 13 are enlarged schematic views illustrating an example of an interior of a second display panel of FIG. 8;

FIG. 14 is a view for describing the function of a display panel of FIG. 7;

FIG. 15 is a schematic perspective view illustrating a display device according to an embodiment;

FIG. 16 is a schematic cross-sectional view illustrating an example of a cross section taken along line V-V′ of FIG. 15;

FIG. 17 is a schematic perspective view illustrating a display device according to an embodiment;

FIG. 18 is a schematic cross-sectional view illustrating an example of a cross section taken along line VI-VI′ of FIG. 17; and

FIG. 19 is a diagram illustrating an example of an electronic device according to embodiments;

FIG. 20 is an example diagram showing a virtual reality device including a display device according to an embodiment;

FIG. 21 is an example diagram showing a smart device including a display device according to an embodiment;

FIG. 22 is a diagram of an example showing a vehicle including a display device according to an embodiment; and

FIG. 23 is a diagram of an example showing a transparent display device including a display device according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are described below, by referring to the figures, to explain aspects.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

While the disclosure includes various modifications and alternative forms, given embodiments thereof are shown by way of example in the drawings and will herein be described in detail. Advantages and features of the disclosure and methods for accomplishing the same will be more clearly understood from embodiments described below with reference to the drawings. However, the disclosure is not limited to the embodiments disclosed below but may be implemented in various forms.

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

As used herein, the singular forms, “a,” “an,” and “the” are intended to include the plural forms as well, unless the context clearly indicates otherwise.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

In the following embodiments, when a unit, region, or component is referred to as being “formed on” another unit, region, or component, it can be directly or indirectly formed on the other unit, region, or component. For example, intervening units, regions, or components may be present.

In the following embodiments, terms such as “connecting” or “coupling” two members do not necessarily mean a direct and/or fixed connection or coupling of the two members, unless the context clearly indicates otherwise, and do not preclude other members from being disposed between the two members.

Sizes of components in the drawings may be exaggerated or reduced for convenience of description. For example, the size and/or thickness of each component shown in the drawings are arbitrarily represented for convenience of description, and thus, the disclosure is not necessarily limited thereto.

Hereinafter, embodiments will be described below in detail with reference to the accompanying drawings, and when the embodiments of the disclosure are described with reference to the drawings, the same or corresponding components are given the same reference numerals, and repetitive descriptions thereof may be omitted.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments may be described and illustrated in the accompanying drawings in terms of functional blocks, units, and/or modules.

Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies.

In the case of the blocks, units, and/or modules being implemented by microprocessors or other similar hardware, they may be programmed and controlled using software (for example, microcode) to perform various functions discussed herein and may optionally be driven by firmware and/or software.

It is also contemplated that each block, unit, and/or module may be implemented by dedicated hardware, or as a combination of dedicated hardware to perform some functions and a processor (for example, one or more programmed microprocessors and associated circuitry) to perform other functions.

Each block, unit, and/or module of embodiments may be physically separated into two or more interacting and discrete blocks, units, and/or modules without departing from the scope of the disclosure.

Further, the blocks, units, and/or modules of embodiments may be physically combined into more complex blocks, units, and/or modules without departing from the scope of the disclosure.

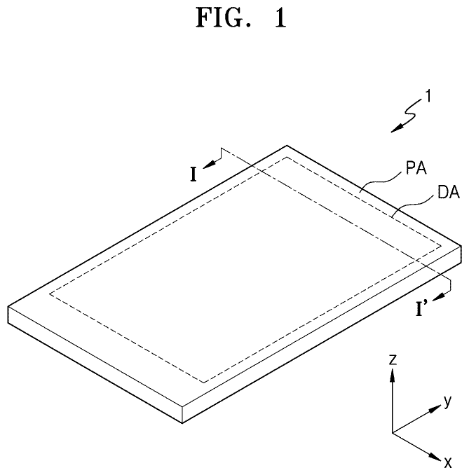

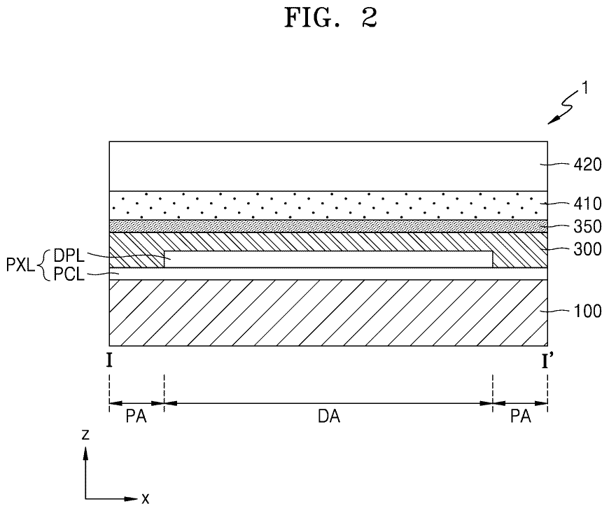

FIG. 1 is a schematic perspective view illustrating a display device according to an embodiment, and FIG. 2 is a schematic cross-sectional view illustrating an example of a cross section taken along line I-I′ of FIG. 1.

Referring to FIG. 1, a display device 1 according to an embodiment of the disclosure may include a display area DA and a peripheral area PA. The peripheral area PA is disposed on the periphery of the display area DA so as to surround (or be adjacent to) the display area DA. Various wirings and a driving circuit part, which transmit electrical signals to be applied to the display area DA, may be positioned in the peripheral area PA. The display device 1 may provide a selectable image using light emitted from pixels disposed in the display area DA. Although not illustrated in the drawing, the display device 1 is bendable in a partial region of the peripheral area PA, the partial region including a bending area.

The display device 1 may include a display device such as an organic light-emitting display device, an inorganic light-emitting display device (or an inorganic electroluminescence (EL) display device), or a quantum-dot light-emitting display device. Hereinafter, an organic light-emitting display device will be described as an example. The display device 1 may be incorporated into various types of electronic devices such as mobile phones, laptop computers, and smart watches. By way of example, the display device 1 may be implemented as a display in an automobile. In this case, the display device 1 may be implemented as at least one of a driver's cluster display, a central information display (CID), or a passenger information display (PID). By way of example, the display device 1 may be implemented as an integrated display in which the driver's cluster display and the central information display (CID) are combined, or as an integrated display in which the driver's cluster display, the central information display (CID), and the passenger information display (PID) are all combined.

As shown in FIG. 2, the display device 1 may include a substrate 100, a pixel layer PXL disposed on the substrate 100, an encapsulation member 300 sealing the pixel layer PXL, a light control layer 350 disposed on the encapsulation member 300, a bonding layer 410 disposed on the light control layer 350, and a functional layer 420 disposed on the bonding layer 410, which are sequentially stacked in a thickness direction (a z-direction).

The substrate 100 may include a glass material or a polymer resin. For example, the substrate 100 may include a glass material having SiO₂ as a main component, or include various flexible or bendable materials, for example, a resin such as reinforced plastic. Although not illustrated in the drawing, the substrate 100 is bendable in a partial region of the peripheral area PA, the partial region having a bending area.

The pixel layer PXL may be disposed on the substrate 100. The pixel layer PXL may include a display element layer DPL including display elements disposed for each pixel, and a pixel circuit layer PCL including a pixel circuit, which is disposed for each pixel, and insulating layers. The display element layer DPL is disposed on top of the pixel circuit layer PCL, and insulating layers may be disposed between the pixel circuit and the display elements. Some wirings of the pixel circuit layer PCL and the insulating layers may extend to the peripheral area PA.

The encapsulation member 300 may include a thin-film encapsulation layer. The thin-film encapsulation layer may include at least one inorganic encapsulation layer and at least one organic encapsulation layer. In case that the display device 1 includes the substrate 100, which may include a polymer resin, and the encapsulation member 300, which is formed as a thin-film encapsulation layer including an inorganic encapsulation layer and an organic encapsulation layer, the flexibility of the display device 1 may be improved.

The light control layer 350 may adjust a path of light emitted from the display elements of the display element layer DPL and improve a light emission efficiency of the display device 1. As will be described below, the light control layer 350, together with the bonding layer 410, may increase a light extraction efficiency of the display device 1 by changing the path of light emitted from the display elements.

The bonding layer 410 bonds the functional layer 420 above the encapsulation member 300 to the underlying layer, such as the light control layer 350. The bonding layer 410 can improve the light extraction efficiency of the display device 1 by having a higher refractive index than the light control layer 350.

The functional layer 420 may include a polarizing layer. The polarizing layer transmits only light that vibrates in the same direction as a polarization axis thereof among the light emitted from the display elements of the display element layer DPL, and absorbs or reflects light that vibrates in different directions. The functional layer 420 may further include an optical film, a window, or the like to reflect external light.

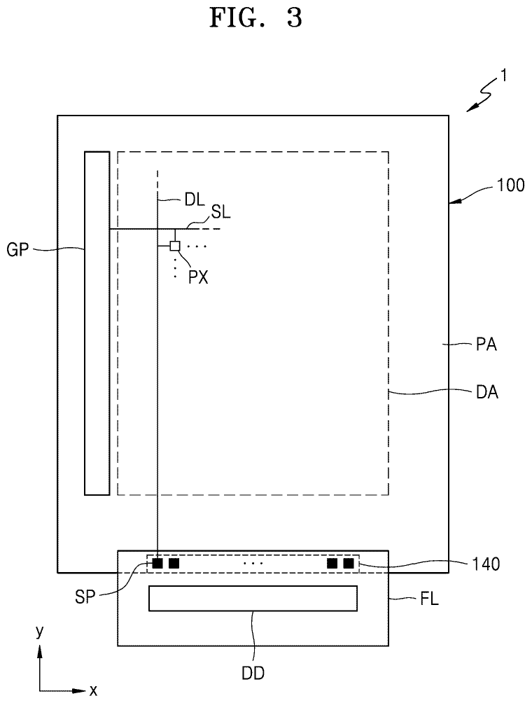

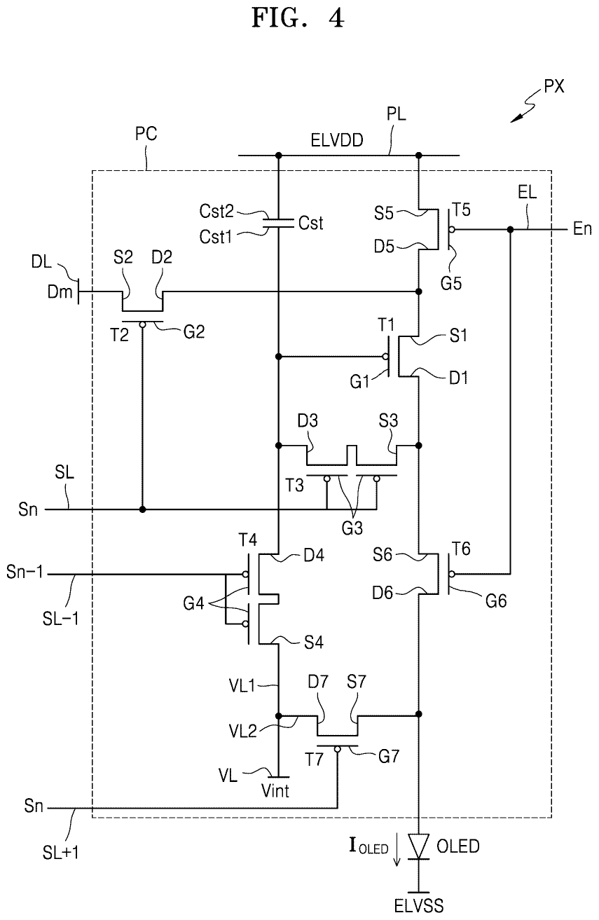

FIG. 3 is a schematic plan view illustrating a portion of the display device of FIG. 1, and FIG. 4 is a schematic diagram of an equivalent circuit illustrating an example of one pixel of the display device of FIG. 1.

Referring to FIG. 3, the substrate 100 may include the display area DA and the peripheral area PA. The peripheral area PA may be positioned on the periphery of the display area DA, and may surround the display area DA.

Pixels PX arranged or disposed in a selectable pattern in a first direction (an x-direction or a row direction) and a second direction (a y-direction or a column direction) may be provided in the display area DA over the substrate 100.

In the peripheral area PA above the substrate 100, a scan driver GP configured to provide a scan signal to each of the pixels PX, a data driver DD configured to a data signal to each of the pixels PX, main power wirings (not shown) configured to provide a driving voltage ELVDD (see FIG. 4) and a common voltage ELVSS (see FIG. 4), and the like may be disposed. A pad part 140, in which signal pads SP connected to a data line DL are disposed, may be positioned in the peripheral area PA over the substrate 100.

The scan driver GP may include an oxide semiconductor thin-film transistor (TFT) gate driver circuit (ASG) or an amorphous silicon TFT gate driver circuit (ASG). In FIG. 3, the scan driver GP is illustrated as being disposed adjacent to one side or a side of the substrate 100, but according to embodiments, the scan driver GP may also be disposed adjacent to each of two opposite sides of the substrate 100.

FIG. 3 illustrates a chip-on-film (COF) method in which the data driver DD is disposed on a film FL, which is electrically connected to the signal pads SP disposed over the substrate 100. According to an embodiment, the data driver DD may be directly disposed over the substrate 100 by a chip-on-glass (COG) method or a chip-on-plastic (COP) method. The data driver DD may be electrically connected to a flexible printed circuit board (FPCB).

Referring to FIG. 4, one pixel PX may include a pixel circuit PC and an organic light-emitting element OLED electrically connected to the pixel circuit PC.

The pixel circuit PC may include transistors T1 to T7 and a storage capacitor Cst, as illustrated in FIG. 4. The transistors T1 to T7 and the storage capacitor Cst may be connected to signal lines SL, SL−1, SL+1, EL, and DL, a first initialization voltage line VL1, a second initialization voltage line VL2, and a driving voltage line PL.

The signal lines SL, SL−1, SL+1, EL, and DL may include a scan line SL that transmits a scan signal Sn, a previous scan line SL−1 that transmits a previous scan signal Sn−1 to a first initialization transistor T4, a subsequent scan line SL+1 that transmits the scan signal Sn to a second initialization transistor T7, a light emission control line EL that transmits a light emission control signal En to an operation control transistor T5 and a light emission control transistor T6, and the data line DL that crosses or intersects the scan line SL and transmits a data signal Dm. The driving voltage line PL may transmit the driving voltage ELVDD to a driving transistor T1, the first initialization voltage line VL1 may transmit an initialization voltage Vint to the first initialization transistor T4, and the second initialization voltage line VL2 may transmit the initialization voltage Vint to the second initialization transistor T7.

A driving gate electrode G1 of the driving transistor T1 is connected to a lower electrode Cst1 of the storage capacitor Cst, a driving source electrode S1 of the driving transistor T1 is connected to the driving voltage line PL via the operation control transistor T5, and a driving drain electrode D1 of the driving transistor T1 is electrically connected to a pixel electrode of the organic light-emitting element OLED via the light emission control transistor T6. The driving transistor T1 receives the data signal Dm according to a switching operation of a switching transistor T2 and supplies a driving current I_{OLED} to the organic light-emitting element OLED.

A switching gate electrode G2 of the switching transistor T2 is connected to the scan line SL, a switching source electrode S2 of the switching transistor T2 is connected to the data line DL, and a switching drain electrode D2 of the switching transistor T2 is connected to the driving source electrode S1 of the driving transistor T1 and is connected to the driving voltage line PL via the operation control transistor T5. The switching transistor T2 is turned on in response to the scan signal Sn received through the scan line SL and performs a switching operation that transfers the data signal Dm transmitted through the data line DL to the driving source electrode S1 of the driving transistor T1.

A compensation gate electrode G3 of a compensation transistor T3 is connected to the scan line SL, a compensation source electrode S3 of the compensation transistor T3 is connected to the driving drain electrode D1 of the driving transistor T1 and is connected to the pixel electrode of the organic light-emitting element OLED via the light emission control transistor T6, and a compensation drain electrode D3 of the compensation transistor T3 is connected to the lower electrode Cst1 of the storage capacitor Cst, a first initialization drain electrode D4 of a first initialization transistor T4, and the driving gate electrode G1 of the driving transistor T1. The compensation transistor T3 is turned on in response to the scan signal Sn received through the scan line SL to electrically connect the driving gate electrode G1 and the driving drain electrode D1 of the driving transistor T1 to each other, thereby configuring the driving transistor T1 in a diode connection.

A first initialization gate electrode G4 of the first initialization transistor T4 is connected to the previous scan line SL−1, a first initialization source electrode S4 of the first initialization transistor T4 is connected to the first initialization voltage line VL1, and the first initialization drain electrode D4 of the first initialization transistor T4 is connected to the lower electrode Cst1 of the storage capacitor Cst, the compensation drain electrode D3 of the compensation transistor T3, and the driving gate electrode G1 of the driving transistor T1. The first initialization transistor T4 is turned on in response to the previous scan signal Sn−1 received through the previous scan line SL−1 and performs an initialization operation that transfers the initialization voltage Vint to the driving gate electrode G1 of the driving transistor T1 to initialize a voltage of the driving gate electrode G1 of the driving transistor T1.

An operation control gate electrode G5 of the operation control transistor T5 is connected to the light emission control line EL, an operation control source electrode S5 of the operation control transistor T5 is connected to the driving voltage line PL, and an operation control drain electrode D5 of the operation control transistor T5 is connected to the driving source electrode S1 of the driving transistor T1 and the switching drain electrode D2 of the switching transistor T2.

A light emission control gate electrode G6 of the light emission control transistor T6 is connected to the light emission control line EL, a light emission control source electrode S6 of the light emission control transistor T6 is connected to the driving drain electrode D1 of the driving transistor T1 and the compensation source electrode S3 of the compensation transistor T3, and a light emission control drain electrode D6 of the light emission control transistor T6 is electrically connected to a second initialization source electrode S7 of the second initialization transistor T7 and the pixel electrode of the organic light-emitting element OLED.

The operation control transistor T5 and the light emission control transistor T6 are simultaneously turned on in response to the light emission control signal En received through the light emission control line EL to allow the driving voltage ELVDD to be supplied to the organic light-emitting element OLED, thereby causing the driving current I_{OLED} to flow through the organic light-emitting element OLED.

A second initialization gate electrode G7 of the second initialization transistor T7 is connected to the subsequent scan line SL+1, the second initialization source electrode S7 of the second initialization transistor T7 is connected to the light emission control drain electrode D6 of the light emission control transistor T6 and the pixel electrode of the organic light-emitting element OLED, and a second initialization drain electrode D7 of the second initialization transistor T7 is connected to the second initialization voltage line VL2.

The scan line SL and the subsequent scan line SL+1 are electrically connected to each other, allowing the same scan signal Sn to be applied to both the scan line SL and the subsequent scan line SL+1. Accordingly, the second initialization transistor T7 may be turned on in response to the scan signal Sn received through the subsequent scan line SL+1 and perform an operation to initialize the pixel electrode of the organic light-emitting element OLED.

An upper electrode Cst2 of the storage capacitor Cst is connected to the driving voltage line PL, and a common electrode of the organic light-emitting element OLED is connected to the common voltage ELVSS. Accordingly, the organic light-emitting element OLED can display an image by emitting light in response to the driving current I_{OLED} received from the driving transistor T1.

In FIG. 4, the compensation transistor T3 and the first initialization transistor T4 are illustrated as each having dual gate electrodes, but the compensation transistor T3 and the first initialization transistor T4 may each have a single gate electrode.

While the structure of one pixel circuit PC is described in FIG. 4, pixels PX with the same pixel circuit PC may be arranged or disposed to form rows, and in this configuration, the first initialization voltage line VL1, the previous scan line SL−1, the second initialization voltage line VL2, and the subsequent scan line SL+1 can be shared by adjacent pixels. In FIG. 4, the pixels PX may include an initialization voltage line VL.

For example, the first initialization voltage line VL1 and the previous scan line SL−1 may be electrically connected to the second initialization transistor of another pixel circuit PC disposed in the second direction (y-direction). Accordingly, the previous scan signal applied to the previous scan line SL−1 may be transmitted as a subsequent scan signal to the second initialization transistor of the another pixel circuit PC. Similarly, the second initialization voltage line VL2 and the subsequent scan line SL+1 may be electrically connected to the first initialization transistor of another pixel circuit PC disposed adjacent thereto in the second direction (y-direction) based on the drawing to transmit the previous scan signal and the initialization voltage.

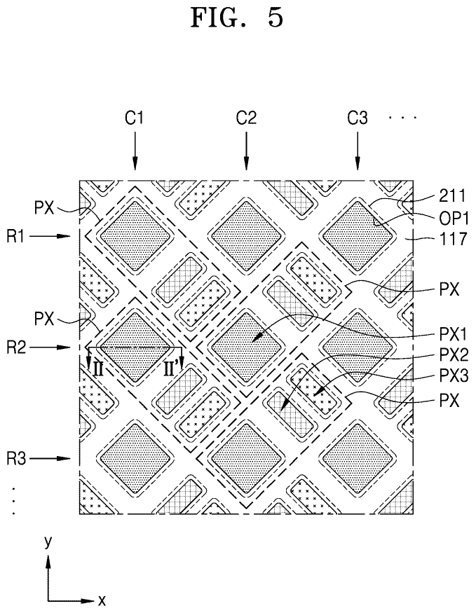

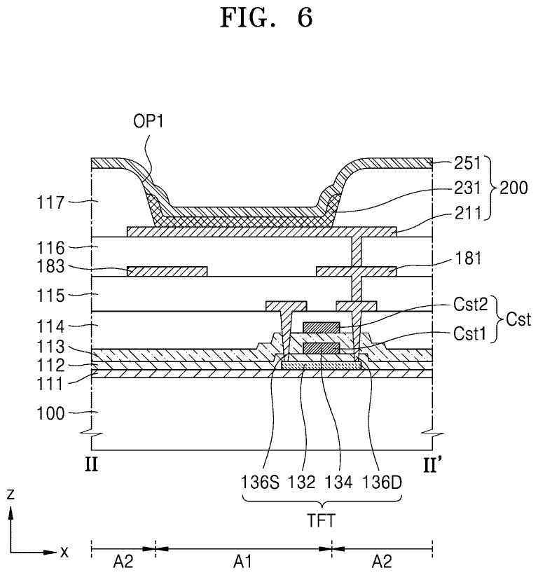

FIG. 5 is a partial schematic plan view illustrating an example of a pixel arrangement of the display device of FIG. 1, and FIG. 6 is a schematic cross-sectional view illustrating an example of a cross section taken along line II-II′ of FIG. 5.

Referring to FIG. 5, the pixels PX may each include a first pixel PX1, a second pixel PX2, and a third pixel PX3. The first pixel PX1, the second pixel PX2, and the third pixel PX3 may be repeatedly disposed according to a selectable pattern.

In an embodiment, the second pixel PX2 and the third pixel PX 3, which are adjacent to the first pixel PX1, may be disposed side by side. Referring to FIG. 5, for example, it can be seen that the second pixel PX2 and the third pixel PX3, which are disposed side by side, are disposed around one first pixel PX1.

The first pixel PX1, the second pixel PX2, and the third pixel PX3 may each include a pixel circuit and an organic light-emitting diode (OLED) electrically connected to the pixel circuit. The organic light-emitting diode (OLED) of each pixel may be disposed directly above the pixel circuit of the corresponding pixel so as to overlap, or may be disposed offset from the pixel circuit of the corresponding pixel to overlap the pixel circuit of a pixel in an adjacent row or column. The arrangement of the pixels may be the arrangement of the organic light-emitting diode (OLED) of each of the first pixel PX1, the second pixel PX2, and the third pixel PX3, or the arrangement of pixel electrodes 211 that form the organic light-emitting diodes (OLEDs).

The pixels PX each including the first pixel PX1, the second pixel PX2, and the third pixel PX3 may be disposed according to a selectable pattern.

In an embodiment, the pixels PX may be disposed such that the pixels PX disposed in a first direction and the pixels PX disposed in a second direction that is rotated by about 90° from the first direction are disposed in a zigzag pattern.

For example, referring to FIG. 5 again, some of the pixels PX may be disposed in the first direction (a direction rotated by about −45° from an x-axis). In this case, the second pixel PX2 adjacent to the first pixel PX1 may be disposed at a location spaced apart from the first pixel PX1 by a selectable distance in the first direction, and the third pixel PX3 may be disposed at a location spaced apart from the second pixel PX2 by a selectable distance in the first direction. Some of the pixels PX may be disposed in the second direction (a direction rotated by about +45° from the x-axis). Here, the second direction may be a direction rotated by about 90° from the first direction. In this case, the second pixel PX2 adjacent to the first pixel PX1 may be disposed at a location spaced apart from the first pixel PX1 by a selectable distance in the second direction, and the third pixel PX3 may be disposed at a location spaced apart from the second pixel PX2 by a selectable distance in the second direction. As described above, by arranging the pixels PX disposed in the first direction alternately with the pixels PX disposed in the second direction, the pixels PX may be disposed to form a selectable pattern.

In an embodiment, the pixels PX may be disposed diagonally with respect to a width direction of the display panel (x-direction). For example, the pixels PX may be disposed diagonally with respect to a width direction of the substrate 100 (x-direction).

In a given embodiment, the pixels PX may be disposed in a direction rotated by about ±45° from the width direction of the display panel (x-direction). Accordingly, in case that the first pixel PX1 is used as a reference in each pixel PX, the first pixels PX1 may be disposed to be spaced apart from each other along each row R1, R2, R3, . . . , and each column C1, C2, C3, . . .

As described above, the display device according to the disclosure can have improved optical characteristics, enhanced visibility, and favorable advantages regarding external light reflection, by arranging the pixels PX in a given pattern. For example, as will be described below, the reduction in visibility can be minimized even in case that light emitted from the pixel PX passes through a louver structure of a light control member. The issue of interference patterns caused by the louver structure of the light control member can be prevented or reduced. A phenomenon where the content displayed on the display device becomes difficult for a user to perceive due to external light can be reduced. The display device according to the disclosure may, of course, have additional effects due to the aforementioned pattern of the pixels PX.

At least two of the first pixel PX1, the second pixel PX2, and the third pixel PX3 may have different areas. The pixel electrode 211 of the first pixel PX1, the pixel electrode 211 of the second pixel PX2, and the pixel electrode 211 of the third pixel PX3 may have different areas.

In an embodiment, the first pixel PX1 may have a larger area than the second pixel PX2 and the third pixel PX3. The second pixel PX2 and the third pixel PX3 may have the same area. In this case, the pixel electrode 211 of the first pixel PX1 may have a larger area than the pixel electrode 211 of the adjacent second pixel PX2 and the pixel electrode 211 of the adjacent third pixel PX3. The pixel electrode 211 of the second pixel PX2 may have the same area as the pixel electrode 211 of the adjacent third pixel PX3.

In an embodiment, the pixel electrode 211 may have shapes including a polygonal shape, such as a quadrangular shape and an octagonal shape, a circular shape, and an elliptical shape, and the polygonal shape may have a shape having round vertexes.

The first pixel PX1, the second pixel PX2, and the third pixel PX3 may release light of different colors. For example, the first pixel PX1, the second pixel PX2, and the third pixel PX3 may emit light of different colors.

In an embodiment, the first pixel PX1 may be a blue pixel that emits blue light, the second pixel PX2 may be a red pixel that emits red light, and the third pixel PX3 may be a green pixel that emits green light. However, the disclosure is not limited thereto, and the first pixel PX1, the second pixel PX2, and the third pixel PX3 may emit light in colors different from those described above.

The display area DA of the substrate 100 may include a first area A1 and a second area A2 around the first area A1. The first area A1 may be an area in which the organic light-emitting diode (OLED) of each of the first pixel PX1, the second pixel PX2, and the third pixel PX3 is positioned. The pixel electrode 211 is disposed in the first area A1, and the area of the first area A1 may be smaller than the area of the pixel electrode 211. The second area A2 is an area surrounding the first area A1, and is an area positioned between first areas A1. A third insulating layer 117 may be disposed in the second area A2. The first area A1 corresponds to an area of the pixel electrode 211 exposed by a first opening OP1 of the third insulating layer 117, and the second area A2 corresponds to an area between the pixel electrodes 211, in which the third insulating layer 117 is disposed. Accordingly, the first area A1 and the second area A2 of the substrate 100 may be respectively understood as the first area A1 and the second area A2 of the pixel PX. In the specification, the first area A1 is defined as an area corresponding to a bottom surface of the first opening OP1, which has the minimum area when viewed from above. In FIG. 5, the outline of the bottom surface of the first opening OP1 is indicated by a solid line, and the outline of the pixel electrode 211 is indicated by a dotted line.

Referring to FIG. 6, a buffer layer 111 may be disposed on the substrate 100 to prevent impurities from penetrating into a semiconductor layer of a thin-film transistor.

The substrate 100 may be formed of various materials such as glass, metal, or plastic. According to an embodiment, the substrate 100 may be a flexible substrate and may include, for example, polymer resins such as polyethersulfone (PES), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), or cellulose acetate propionate (CAP).

The buffer layer 111 may include an inorganic insulating material such as silicon nitride or silicon oxide, and may be a single layer or a multilayer.

A thin-film transistor TFT, a capacitor Cst, and an organic light-emitting diode 200 electrically connected to the thin-film transistor TFT may be disposed on the substrate 100. The electrical connection of the organic light-emitting diode 200 to the thin-film transistor TFT may be understood as an electrical connection of the pixel electrode 211 to the thin-film transistor TFT. The thin-film transistor TFT may be the driving transistor T1 of FIG. 4.

The thin-film transistor TFT may include a semiconductor layer 132, a gate electrode 134, a source electrode 136S, and a drain electrode 136D. The semiconductor layer 132 may include an oxide semiconductor material. The semiconductor layer 132 may include amorphous silicon, polycrystalline silicon, or an organic semiconductor material. The gate electrode 134 may be formed as a single layer or a multilayer with one or more materials selected from, for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu) by taking into account adhesion with an adjacent layer, surface flatness of a stacked layer, and processability.

A gate insulating layer 112 including an inorganic material such as silicon oxide, silicon nitride, and/or silicon oxynitride may be disposed between the semiconductor layer 132 and the gate electrode 134. A first interlayer insulating layer 113 and a second interlayer insulating layer 114, each of which may include an inorganic material such as silicon oxide, silicon nitride and/or silicon oxynitride, may be disposed between the gate electrode 134, and the source electrode 136S and the drain electrode 136D. The source electrode 136S and the drain electrode 136D may each be electrically connected to the semiconductor layer 132 through contact holes formed in the gate insulating layer 112, the first interlayer insulating layer 113, and the second interlayer insulating layer 114.

The source electrode 136S and the drain electrode 136D may each be formed as a single layer or a multilayer with one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The capacitor Cst may include the lower electrode Cst1 and the upper electrode Cst2 that overlap each other with the first interlayer insulating layer 113 disposed therebetween. The capacitor Cst may overlap the thin-film transistor TFT. In FIG. 6, the gate electrode 134 of the thin-film transistor TFT is illustrated as being the lower electrode Cst1 of the capacitor Cst. In an embodiment, the capacitor Cst may not overlap the thin-film transistor TFT. The capacitor Cst may be covered by the second interlayer insulating layer 114.

The pixel circuit including the thin-film transistor TFT and the capacitor Cst may be covered with a first insulating layer 115 and a second insulating layer 116. The first insulating layer 115 and the second insulating layer 116 may be organic insulating layers serving as planarization insulating layers. The first insulating layer 115 and the second insulating layer 116 may include a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof. In an embodiment, the first insulating layer 115 and the second insulating layer 116 may each include polyimide.

A display element, for example, the organic light-emitting diode 200, may be disposed on the second insulating layer 116. The organic light-emitting diode 200 may include the pixel electrode 211, an intermediate layer 231, and an opposite electrode 251.

The pixel electrode 211 is disposed on the second insulating layer 116, and may be connected to the thin-film transistor TFT through a connection electrode 181 disposed on the first insulating layer 115. A wiring 183 such as the data line DL and a driving voltage line PL may be disposed on the first insulating layer 115.

The pixel electrode 211 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 211 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, the pixel electrode 211 may further include a film formed of ITO, IZO, ZnO or In₂O₃ on/below the above-described reflective film.

The third insulating layer 117 may be disposed on the second insulating layer 116. The third insulating layer 117 may be a pixel defining layer that covers edges of the pixel electrode 211 and defines a pixel by including the first opening OP1 that exposes a portion of the pixel electrode 211. The first opening OP1 may correspond to the first area A1. The third insulating layer 117 may prevent arching or the like from occurring at the edges of the pixel electrode 211 by increasing a distance between the edges of the pixel electrode 211 and the opposite electrode 251. The third insulating layer 117 may be formed of an organic material such as polyimide (PI) or hexamethyldisiloxane (HMDSO).

The intermediate layer 231 may include a light-emitting layer. The light-emitting layer may include a polymer organic material or a low-molecular-weight organic material that emits light having a selectable color. In an embodiment, the intermediate layer 231 may include a first functional layer disposed below the light-emitting layer and/or a second functional layer disposed on the light-emitting layer. The first functional layer and/or the second functional layer may include a layer which is one body over pixel electrodes 211, or may include a layer patterned to respectively correspond to the pixel electrodes 211.

The first functional layer may be a single layer or a multilayer. For example, in case that the first functional layer is formed of a polymer material, the first functional layer may include a hole transport layer (HTL), which has a single-layer structure, and may be formed of poly(3,4-ethylenedioxythiophene) (PEDOT) or polyaniline (PANI). In case that the first functional layer is formed of a low-molecular weight material, the first functional layer may include a hole injection layer (HIL) and a hole transport layer (HTL).

The second functional layer may be omitted. For example, in case that the first functional layer and the light-emitting layer are formed of a polymer material, the second functional layer may be formed to improve the characteristics of the organic light-emitting diode. The second functional layer may be a single layer or a multilayer. The second functional layer may include an electron transport layer (ETL) and/or an electron injection layer (EIL).

The opposite electrode 251 is disposed to face the pixel electrode 211 with the intermediate layer 231 disposed between the opposite electrode 251 and the intermediate layer 231. The opposite electrode 251 may be made of a conductive material having a low work function. For example, the opposite electrode 251 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. By way of example, the opposite electrode 251 may further include a layer on the (semi) transparent layer including the above-described material, the layer including ITO, IZO, ZnO, or In₂O₃.

The opposite electrode 251 may be disposed on top of the intermediate layer 231 and the third insulating layer 117. The opposite electrode 251 may be formed as one body over organic light-emitting diodes 200 in the display area DA and may face the pixel electrodes 211.

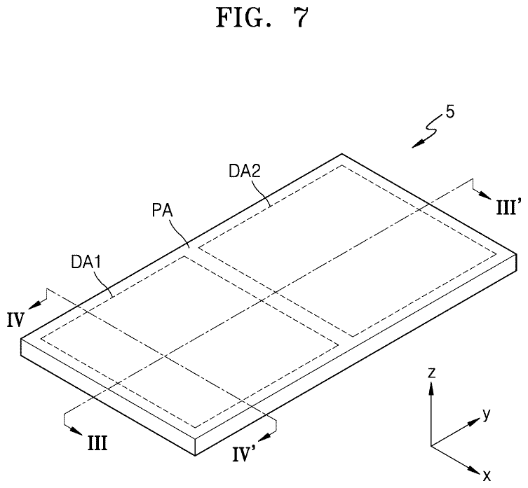

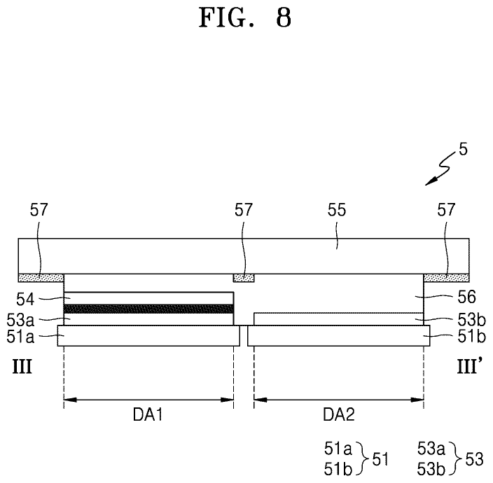

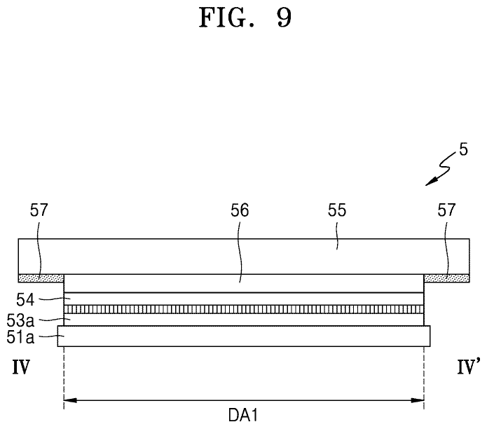

FIG. 7 is a schematic perspective view illustrating a display device according to an embodiment, FIG. 8 is a schematic cross-sectional view illustrating an example of a cross section taken along line III-III′ of FIG. 7, and FIG. 9 is a schematic cross-sectional view illustrating an example of a cross section taken along line IV-IV′ of FIG. 7.

Hereinafter, for convenience of description, details that are identical to those previously described or that can be readily applied by a person of ordinary skill in the art to which the disclosure pertains may be omitted or briefly described.

Referring to FIGS. 7 to 9, a display device 5 according to an embodiment of the disclosure may include a display panel 51.

The display panel 51 may include at least one of the substrate 100, the organic light-emitting diode 200, and the encapsulation member 300 described with reference to FIGS. 1 to 6. For example, the display panel 51 may include all of the substrate 100, the organic light-emitting diode 200, and the encapsulation member 300 described with reference to FIGS. 1 to 6. However, the disclosure is not limited thereto, and the display panel 51 may further include additional components that perform other functions. As an example, the display panel 51 may further include various components such as the light control layer 350 and the functional layer 420 to change a light path or improve light extraction efficiency.

The display panel 51 may be divided into a first display area DA1, a second display area DA2, and a peripheral area PA. For example, the first display area DA1 and the second display area DA2 may be spaced apart from each other so as to be distinguishable. The peripheral area PA may be disposed to surround the first display area DA1 and the second display area DA2.

The display device 5 may provide a selectable image using light emitted from pixels disposed in the first display area DA1 and the second display area DA2. For example, the first display area DA1 and the second display area DA2 may provide different images. As another example, the first display area DA1 and the second display area DA2 may also provide the same image. As another example, the first display area DA1 and the second display area DA2 may also provide images that are continuous with each other.

The display panel 51 may include a first display panel 51a disposed in a location corresponding to the first display area DA1 and a second display panel 51b disposed in a location corresponding to the second display area DA2.

The first display panel 51a and the second display panel 51b may be distinguishable from each other. For example, the first display panel 51a and the second display panel 51b may be independent panels.

In the drawing, the first display panel 51a and the second display panel 51b are illustrated as being disposed to be spaced apart from each other, but may also be disposed to be in contact with each other.

A first polarizing layer 53a may be disposed on the first display panel 51a.

The first polarizing layer 53a is disposed on the first display panel 51a, and may transmit only light vibrating in the same direction as a polarization axis thereof among light emitted from display elements of a display element layer DPL disposed in the first display panel 51a, and may absorb or reflect light vibrating in other directions.

A second polarizing layer 53b may be disposed on the second display panel 51b.

The second polarizing layer 53b is disposed on the second display panel 51b, and may transmit only light vibrating in the same direction as a polarization axis thereof among light emitted from display elements of a display element layer DPL disposed in the second display panel 51b, and may absorb or reflect light vibrating in other directions.

The first polarizing layer 53a and the second polarizing layer 53b may be formed identical to each other to perform the same function, but are not limited thereto, and may be formed to differ from each other as needed. A polarizing layer 53 may include the first polarizing layer 53a and the second polarizing layer 53b of FIG. 8.

The display device 5 may include a light control member. For example, the display device 5 may include a first light control member 54 disposed in the first display area DA1. For example, the first light control member 54 may be disposed above the first display panel 51a.

The first light control member 54 is disposed above the first display panel 51a, and may perform a function of controlling light emitted from the display elements of the display element layer DPL disposed in the first display panel 51a or external light EXL. For example, the first light control member 54 may function to adjust the directionality, transmittance, brightness, or the like of light.

In an embodiment, the first light control member 54 may include a light-absorbing layer (not shown) that absorbs at least a portion of light emitted from the first display panel 51a or external light EXL. For example, the light-absorbing layer (not shown) may absorb at least a portion of the light emitted by the first display panel 51a or external light EXL, thereby preventing or reducing reflected light of an image, which is displayed by the first display panel 51a or the external light EXL, from converging at a given position, wherein the reflected light is reflected by the display device 5. Accordingly, the display device 5 can provide a clearer and sharper image to a user, and visibility can be improved.

The first light control member 54 may further include a polymer layer (not shown) that is disposed on one surface or a surface of the light-absorbing layer (not shown) and formed of a transparent or semi-transparent material. For example, the polymer layer (not shown) may have a structure formed by dispersing liquid crystal molecules in a polymer matrix. As an example, in the polymer layer (not shown), the liquid crystal molecules can be aligned by an applied voltage, thereby adjusting light transmittance.

In an optional embodiment, the first light control member 54 may further include a coating layer (not shown) that performs various functions.

The first light control member 54 may have a louver structure. For example, the louver structure may include an assembly of slats, blades, or panels that are angled to allow air or light to pass through while preventing unwanted elements like rain, direct sunlight, or debris.

The louver structure may be formed by arranging light-absorbing materials, which are formed to extend to have a length, parallel to each other. For example, it can also be described that the louver structure forms a lattice structure.

The light-absorbing material may include carbon black, but the disclosure is not limited thereto, and any material that appears black or can absorb light may be used as the light-absorbing material.

The first light control member 54 may be formed by laminating the light-absorbing layer (not shown) on one surface or a surface of the polymer layer (not shown). The light-absorbing layer (not shown) may be formed of a same material as the polymer layer (not shown) but may be formed in such a manner that the light-absorbing material is inserted from one surface or a surface of the light-absorbing layer (not shown) toward the inside to form a louver structure.

As such, the first light control member 54 can adjust the directionality, transmittance, brightness, or the like of light through the louver structure. For example, in case that light is incident on the first light control member 54 at an oblique angle greater than a selectable angle in a given direction, the light may be absorbed by the light-absorbing layer. In contrast, in case that light is incident on the first light control member 54 at an angle equal to or less than a selectable angle in a given direction, the light may pass through the light-absorbing layer.

In an embodiment, the louver structure may be formed in a direction parallel to a width direction of the display panel 51 (y-direction). Referring to FIG. 8, it can be seen that a louver structure is formed inside the first light control member 54, extending parallel to the width direction of the display panel 51 (y-direction). Referring to FIG. 9, it can be seen that the louver structure of the first light control member 54 is formed as a multilayer structure in a height direction of the display panel 51 (x-direction).

As a result, based on FIG. 7, an image displayed in the first display area DA1 may not be emitted in a vertical direction. As a given example, in case that the display device 5 according to an embodiment is used for a display in an automobile, the first display area DA1 may correspond to a driver's cluster display. Accordingly, the first light control member 54 may prevent an image displayed on the cluster display from reflecting on the windshield or reduce the degree of reflection.

The display device 5 may further include a window 55. The window 55 may be disposed on the display panel 51 to cover the first display area DA1 and the second display area DA2.

Here, the term “being disposed on the display panel 51” does not necessarily mean being disposed directly above the display panel 51, but may include a case in which additional components or layers are further disposed between the display panel 51 and the window 55.

In a given embodiment, the window 55 may be configured to cover the first display area DA1 and the second display area DA2. For example, the window 55 may be configured as a single window to cover both an upper side of the first display panel 51a and an upper side of the second display panel 51b.

To describe this from another perspective, it can also be described that the components corresponding to the first display area DA1 (for example, the first display panel 51a, the first polarizing layer 53a, the light control member, and the like) and the components corresponding to the second display area DA2 (for example, the second display panel 51b, the second polarizing layer 53b, and the like) may be attached to the single window 55. For example, the window 55 may be multi-laminated on top of the components corresponding to the first display area DA1 and the components corresponding to the second display area DA2.

Accordingly, the display device 5 may perform the function of displaying multiple images while being configured as a single device.

In an embodiment, the window 55 may be made of a transparent material. At this time, the window 55 may include materials such as glass or transparent synthetic resin. The window 55 may include at least one or more layers.

In an embodiment, a protective member may be further provided on the window 55. The protective member may be disposed on an upper surface of the window 55 to prevent or minimize scratches or the like from occurring on the window 55. Although not shown in the drawing, in an embodiment, an opaque layer may be disposed on a portion of the protective member. In an embodiment, the opaque layer may be disposed at an edge of the protective member. The opaque layer may block light.

The display device 5 may further include an adhesive layer 56.

The adhesive layer 56 may be disposed between multiple layers forming the display device 5 and function to bond those layers together.

In an embodiment, the adhesive layer 56 may be disposed between the display panel 51 and the window 55. For example, as described above, the first polarizing layer 53a and the light control member may be disposed above the first display panel 51a, and in this case, the adhesive layer 56 may be disposed between the light control member and the window 55 to bond the light control member and the window 55 to each other. The second polarizing layer 53b may be disposed above the second display panel 51b, and in this case, the adhesive layer 56 may be disposed between the light control member and the window 55 to bond the second polarizing layer 53b and the window 55 to each other.

In an embodiment, the adhesive layer 56 may simultaneously bond one window 55 to the components corresponding to the first display area DA1 and the components corresponding to the second display area DA2. Referring to FIG. 8 again, it can be seen that the adhesive layer 56 is disposed between the window 55 and the display panel 51 to simultaneously bond the window 55 to the components corresponding to the first display area DA1 and the components corresponding to the second display area DA2.

The adhesive layer 56 may include a bonding film. As an example, the bonding film may be formed of resins such as acrylic, polyimide, and polycarbonate, which have light-transmitting properties.

The display device 5 may further include a light-blocking member 57.

The light-blocking member 57 may be disposed at one location in the display device 5, and may perform the function of blocking light from passing through unintended areas. For example, the light-blocking member 57 may prevent or reduce the phenomenon in which light emitted from the display elements of the display element layer DPL disposed in the display panel 51 passes through the peripheral area PA of the display device 5, for example, a light leakage phenomenon. Here, the light-blocking member 57 may also be referred to as a black matrix (BM) or a light leakage prevention member, but is not limited to these terms or expressions.

The light-blocking member 57 may include a material that does not transmit light. As an example, the light-blocking member 57 may include carbon black.

In an embodiment, the light-blocking member 57 may be disposed to overlap at least a portion of the periphery of the first display area DA1 and the second display area DA2. For example, as shown in FIGS. 8 and 9, the light-blocking member 57 may be disposed below the window 55 to surround the first display area DA1 and the second display area DA2. Accordingly, the light-blocking member 57 may prevent or reduce the light leakage phenomenon occurring around the periphery of the first display panel 51a and the second display panel 51b.

In an embodiment, the light-blocking member 57 may be disposed to overlap the boundary between the first display area DA1 and the second display area DA2. For example, as shown in FIG. 8, the light-blocking member 57 may be disposed below the window 55 and positioned corresponding to the boundary between the first display area DA1 and the second display area DA2. Accordingly, the light-blocking member 57 may prevent or reduce the problem that light emitted from the display elements of the display element layer DPL disposed in the first display panel 51a penetrates into the second display area DA2, or light emitted from the display element of the display element layer DPL disposed in the second display panel 51b penetrates into the first display area DA1. Accordingly, the first display area DA1 and the second display area DA2 can display images clearly and distinctly without being disturbed by light emitted from each other.

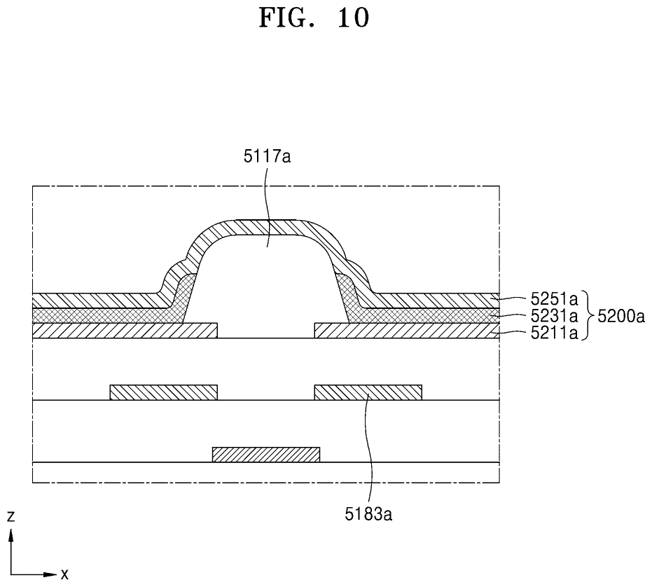

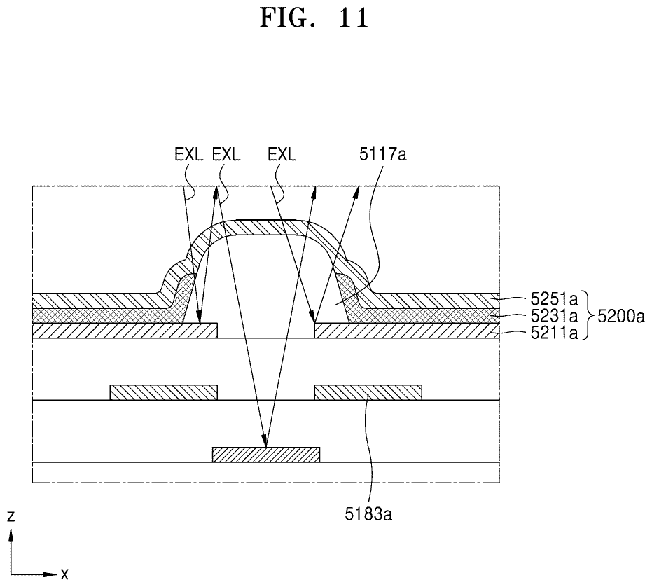

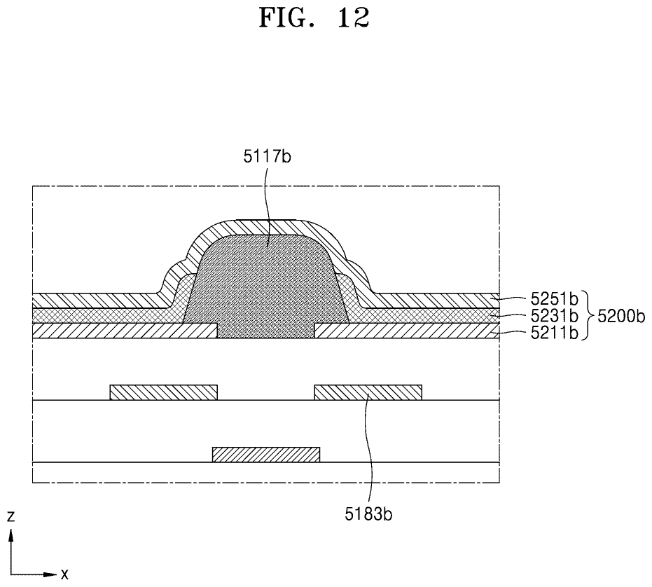

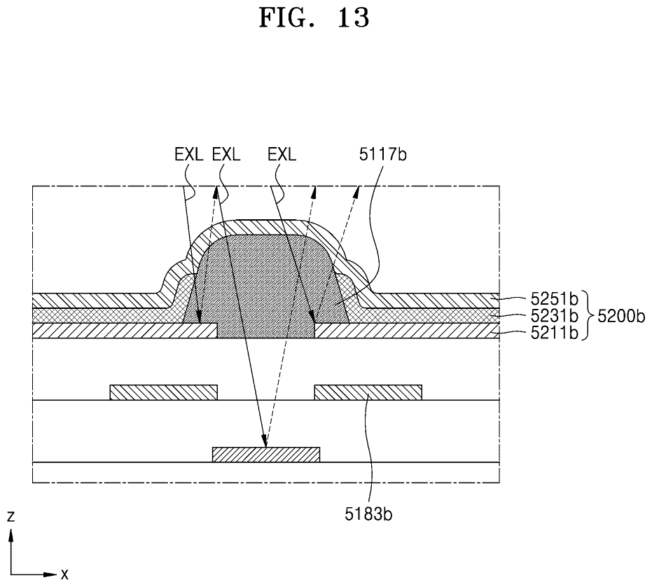

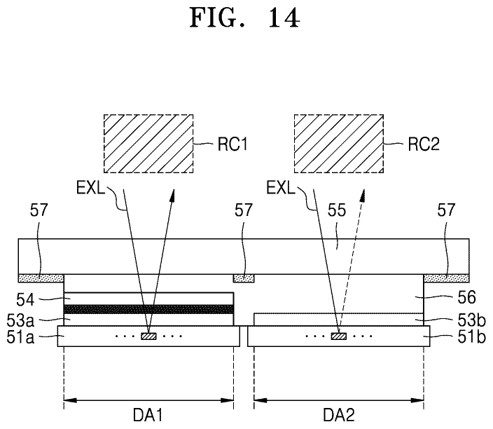

FIGS. 10 and 11 are enlarged views illustrating an example of an interior of the first display panel 51a of FIG. 8, and FIGS. 12 and 13 are enlarged views illustrating an example of an interior of the second display panel 51b of FIG. 8. FIG. 14 is a view for describing the function of the display panel 51 of FIG. 7.

Hereinafter, for convenience of description, details identical to the internal structure of the display panel 51 described with reference to FIG. 6, or details that can be readily understood or applied by a person of ordinary skill in the art to which the disclosure pertains may be omitted or briefly described.

Referring to FIG. 6 and FIGS. 10 to 14, the display panels 51 may each include a substrate, a pixel defining layer, and wirings.

The first display panel 51a may include a first substrate, and a first pixel defining layer 5117a that is disposed on the first substrate and defines pixels. By way of example, the first display panel 51a may include insulating layers disposed on the substrate, among which a first organic light-emitting diode 5200a that emits light may be disposed on the second insulating layer 116. The first organic light-emitting diode 5200a may include a first pixel electrode 5211a, a first intermediate layer 5231a, and a first opposite electrode 5251a. A first wiring 5183a, such as a data line DL or a driving voltage line PL, may be disposed on the first insulating layer 115. Here, the first wiring 5183a may include a metal material. The first wiring 5183a may be disposed between the first substrate and the first pixel defining layer 5117a.

The third insulating layer 117 may be disposed on the second insulating layer 116. The third insulating layer 117 may include the first pixel defining layer 5117a that covers an edge of the first pixel electrode 5211a and defines a pixel by having the first opening OP1 that exposes a portion of the first pixel electrode 5211a.

The first pixel defining layer 5117a may be formed of a polymer resin. For example, the first pixel defining layer 5117a may be formed to include materials such as a polyacrylate-based resin or a polyimide-based resin. The first pixel defining layer 5117a may be formed to further include an inorganic material in addition to the polymer resin. For example, the first pixel defining layer 5117a may be formed to include materials such as silicon nitride (SiNₓ), silicon oxide (SiOₓ), or silicon oxynitride (SiOₓN_{y}).

In an embodiment, the first pixel defining layer 5117a may be formed of a transparent material. In this case, the external light EXL incident on the first display panel 51a may pass through the first pixel defining layer 5117a.

Thus, the external light EXL may pass through the first pixel defining layer 5117a and reach the first wiring 5183a, and may be reflected by the metal at the first wiring 5183a.

The second display panel 51b may include a second substrate and a second pixel defining layer 5117b that is disposed on the second substrate and defines pixels. By way of example, the second display panel 51b may include insulating layers disposed on the substrate, among which a second organic light-emitting diode 5200b that emits light may be disposed on the second insulating layer 116. The second organic light-emitting diode 5200b may include a second pixel electrode 5211b, a second intermediate layer 5231b, and a second opposite electrode 5251b. A second wiring 5183b, such as the data line DL or a driving voltage line PL, may be disposed on the first insulating layer 115. Here, the second wiring 5183b may include a metal material. The second wiring 5183b may be disposed between the second substrate and the second pixel defining layer 5117b.

The third insulating layer 117 may be disposed on the second insulating layer 116. The third insulating layer 117 may be the second pixel defining layer 5117b that covers an edge of the second pixel electrode 5211b and defines a pixel by having the first opening OP1 that exposes a portion of the second pixel electrode 5211b.

The second pixel defining layer 5117b may be formed of a polymer resin. For example, the second pixel defining layer 5117b may be formed to include materials such as a polyacrylate-based resin or a polyimide-based resin. The second pixel defining layer 5117b may be formed to further include an inorganic material in addition to the polymer resin. For example, the second pixel defining layer 5117b may be formed to include materials such as silicon nitride (SiNₓ), silicon oxide (SiOₓ), or silicon oxynitride (SiOₓN_{y}).

In an embodiment, the second pixel defining layer 5117b may include a black pixel defining layer. For example, the second pixel defining layer 5117b may be formed to include a light-absorbing material, or formed to include black pigments or black dyes. The second pixel defining layer 5117b, which is formed to include black pigments or black dyes, can implement a black pixel defining layer. Carbon black or the like may be used as the black pigments or black dyes in case that forming the second pixel defining layer 5117b, but the disclosure is not limited thereto.

In an embodiment, the second pixel defining layer 5117b is implemented as a black pixel defining layer and may absorb at least a portion of the external light EXL incident on the second display panel 51b.

In a given embodiment, the second pixel defining layer 5117b may be formed to absorb all of the external light EXL incident on the second display panel 51b. For example, the external light EXL incident on the second display panel 51b may not reach the second wiring 5183b. Accordingly, the external light EXL incident on the second display panel 51b may not reach the second wiring 5183b and thus may not be reflected by the metal.

In the following, the mechanism by which the external light EXL is reflected by the display device 5 will be described in detail.

Referring to FIGS. 11, 13, and 14 again, the external light EXL incident on the first display area DA1 may be reflected at the first display area DA1 and exhibit a first reflection color RC1, while the external light EXL incident on the second display area DA2 may be reflected at the second display area DA2 and exhibit a second reflection color RC2.

A portion of the external light EXL incident on the first display area DA1 may enter the louver structure of the first light control member 54 and may be absorbed by the first light control member 54. The external light EXL that has passed through the first light control member 54 may reach the first wiring 5183a through the first pixel defining layer 5117a, and may be reflected by the metal. The external light EXL reflected by the metal may pass through the first pixel defining layer 5117a again, with some passing through the first light control member 54 and being emitted to the outside. The emitted light may exhibit the first reflection color RC1. At this time, the first reflection color RC1 may exhibit complete black or a color close to complete black.

At least a portion of the external light EXL incident on the second display area DA2 may reach the second pixel defining layer 5117b. At this time, the second pixel defining layer 5117b may absorb the external light EXL. Accordingly, a portion of the external light EXL may not pass through the second pixel defining layer 5117b and thus may not reach the second wiring 5183b. The external light EXL may not reach the second wiring 5183b and thus may not be reflected by the metal, and may eventually be reflected at the second display area, exhibiting the second reflection color RC2. At this time, the second reflection color RC2 may exhibit a color close to complete black.

In an embodiment, a difference between a specular component included_b* (SCI_b*) value of the first reflection color RC1 and a specular component included_b* (SCI_b*) value of the second reflection color RC2 may be at least 0 and not more than 3. Accordingly, a user may perceive the first reflection color RC1 and the second reflection color RC2 as identical or nearly similar in case that the first display area DA1 and the second display area DA2 are in an off state. For example, the user may perceive the first reflection color RC1 and the second reflection color RC2 as nearly identical black colors. In case that the difference between a SCI_b* value of the first reflection color RC1 and a SCI_b* value of the second reflection color RC2 exceeds 3, there may be a problem in which the user perceives the first reflection color RC1 and the second reflection color RC2 as different in case that the display device 5 is in the off state.

Specular Component Included (SCI) is a measure of the color of an object including specular reflection, where specular reflection refers to light that strikes a surface perpendicularly and is reflected at the same angle. The term ‘b*’ is used in the Lab* color space, where L* represents lightness and a* and b* represent chromaticity. Specifically, a* denotes the red-green axis, and b* denotes the yellow-blue axis.

Accordingly, in the display device 5 according to an embodiment, the first light control member 54 is disposed at a location corresponding to the first display area DA1, and the second pixel defining layer 5117b disposed on the second display panel 51b is implemented as a black pixel defining layer, thereby allowing the first display area DA1 and the second display area DA2 to provide the same visual perception in the off state of the display device 5.

In an optional embodiment, the first pixel defining layer 5117a may include a black pixel defining layer. For example, unlike the previously described embodiment, the first pixel defining layer 5117a may also be implemented as a black pixel defining layer. In this case, the first reflection color RC1 in the first display area DA1 and the second reflection color RC2 in the second display area DA2 may be perceived by the user as an even closer black color. As an example, the first pixel defining layer 5117a may be formed in the same manner as the second pixel defining layer 5117b described above.

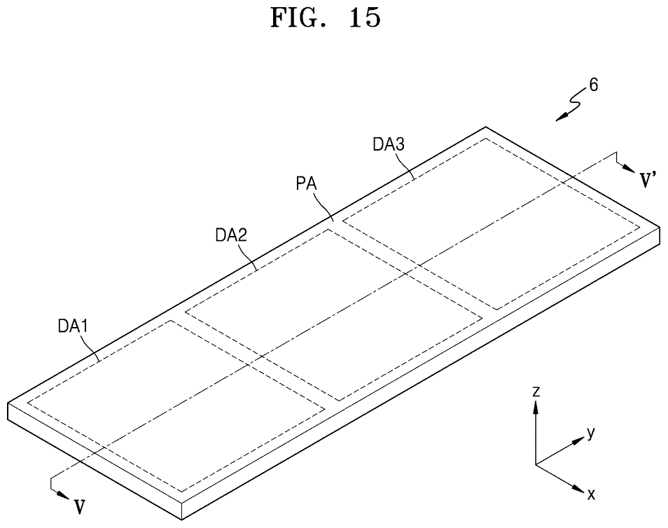

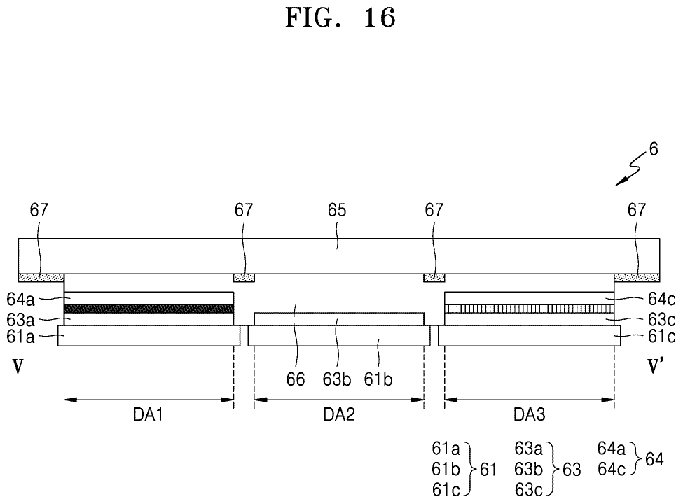

FIG. 15 is a schematic perspective view illustrating a display device according to an embodiment, and FIG. 16 is a schematic cross-sectional view illustrating an example of a cross section taken along line V-V′ of FIG. 15.

A display device 6 according to the embodiment may be different from the above-described embodiments in that a third display area DA3 and components corresponding to the third display area DA3 are further included, and thus, for convenience of description, in the following description, details that are identical to those previously described or that can be readily applied by a person of ordinary skill in the art to which the disclosure pertains may be omitted or briefly described.

Referring to FIGS. 15 to 16, the display device 6 according to an embodiment of the disclosure may include a display panel 61.

The display panel 61 may include at least one of the substrate 100, the organic light-emitting diode 200, and the encapsulation member 300 described with reference to FIGS. 1 to 6. For example, the display panel 61 may include all of the substrate 100, the organic light-emitting diode 200, and the encapsulation member 300 described with reference to FIGS. 1 to 6. However, the disclosure is not limited thereto, and the display panel 61 may further include additional components that perform other functions. As an example, the display panel 61 may further include various components such as the light control layer 350 and the functional layer 420 to change a light path or improve light extraction efficiency.

The display panel 61 may be divided into a first display area DA1, a second display area DA2, a third display area DA3, and a peripheral area PA. For example, the first display area DA1, the second display area DA2, and the third display area DA3 may be spaced apart from each other so as to be distinguishable. The peripheral area PA may be disposed to surround the first display area DA1, the second display area DA2, and the third display area DA3.

The display device 6 may provide a selectable image using light emitted from pixels disposed in the first display area DA1, the second display area DA2, and the third display area DA3. For example, the first display area DA1, the second display area DA2, and the third display area DA3 may provide different images. As another example, the first display area DA1, the second display area DA2, and the third display area DA3 may also provide the same image. As another example, the first display area DA1, the second display area DA2, and the third display area DA3 may also provide images that are continuous with each other.

The display panel 61 may include a first display panel 61a disposed at a location corresponding to the first display area DA1, a second display panel 61b disposed at a location corresponding to the second display area DA2, and a third display panel 61c disposed at a location corresponding to the third display area DA3.

The first display panel 61a, the second display panel 61b, and the third display panel 61c may be distinguished from each other. For example, the first display panel 61a, the second display panel 61b, and the third display panel 61c may be independent panels.

In the drawing, the first display panel 61a, the second display panel 61b, and the third display panel 61c are illustrated as being disposed to be spaced apart from each other, but may also be disposed to be in contact with each other.

A first polarizing layer 63a may be disposed on the first display panel 61a, a second polarizing layer 63b may be disposed on the second display panel 61b, and a third polarizing layer 63c may be disposed on the third display panel 61c.

Each of the first display panel 61a, the second display panel 61b, and the third display panel 61c may transmit only light vibrating in the same direction as a polarization axis thereof among light emitted from display elements of a display element layer DPL disposed in the respective display panels 61, and may absorb or reflect light vibrating in other directions.

The first polarizing layer 63a, the second polarizing layer 63b, and the third polarizing layer 63c may be formed identical to each other to perform the same function, but are not limited thereto, and may be formed to differ from each other as needed. A polarizing layer 63 may include the first polarizing layer 63a, the second polarizing layer 63b and the third polarizing layer 63c of FIG. 16.

The display device 6 may include a light control member 64. For example, the display device 6 may include a first light control member 64a disposed in the first display area DA1 and a third light control member 64c disposed in the third display area DA3. For example, the first light control member 64a may be disposed above the first display panel 61a, and the third light control member 64c may be disposed above the third display panel 61c.

The first light control member 64a and the third light control member 64c may each include a light-absorbing layer (not shown) and a polymer layer (not shown) as described above. In an optional embodiment, each of the first light control member 64a and the third light control member 64c may further include a coating layer (not shown).

Each of the first light control member 64a and the third light control member 64c may have a louver structure.

The louver structure may be formed by arranging light-absorbing materials, which are formed to extend to have a length, parallel to each other. For example, it can also be described that the louver structure forms a lattice structure.

The light-absorbing material may include carbon black, but the disclosure is not limited thereto, and any material that appears black or can absorb light may be used as the light-absorbing material.

The function of the louver structure and the method of forming the louver structure are the same as those described with reference to FIGS. 7 to 9, and thus, a detailed description thereof may be omitted below.

In an embodiment, the louver structure of the first light control member 64a and the louver structure of the third light control member 64c may be formed in different directions.

Accordingly, the first light control member 64a and the third light control member 64c may block light incident from different directions, or adjust the directionality, transmittance, brightness, or the like of the light.

In an optional embodiment, the louver structure of the first light control member 64a and the louver structure of the third light control member 64c may be formed perpendicular to each other.

A given embodiment will be described below.

In an embodiment, the louver structure of the first light control member 64a may be formed in a direction parallel to a width direction of the display panel 61 (y-direction). The louver structure of the first light control member 64a may be formed in a multilayer structure in a height direction of the display panel 61 (x direction). In contrast, the louver structure of the third light control member 64c may be formed in a direction parallel to the height direction of the display panel 61 (x-direction). The louver structure of the third light control member 64c may be formed in a multilayer structure in the width direction of the display panel 61 (y-direction).

As a result, based on FIG. 16, an image displayed in the first display area DA1 may not be emitted in the vertical direction. An image displayed in the third display area DA3 may not be emitted in leftward and rightward directions. As a given example, in case that the display device 6 according to an embodiment is used for a display of an automobile, the first display area DA1 may correspond to a driver's cluster display, and the third display area DA3 may correspond to a passenger information display (PID). Accordingly, the first light control member 64a may prevent an image displayed on the cluster display from reflecting on the windshield or reduce the degree of reflection. An image displayed on the passenger information display (PID) may be directed toward the driver, or may not reflect or may be reduced in reflection on the driver's side windshield.

The display device 6 may further include a window 65. The window 65 may be disposed on the display panel 61 to cover the first display area DA1, the second display area DA2, and the third display area DA3.

Here, the term “being disposed on the display panel 61” does not necessarily mean being disposed directly above the display panel 61, but may include a case in which additional components or layers are further disposed between the display panel 61 and the window 65.

In a given embodiment, the window 65 may be provided to cover the first display area DA1, the second display area DA2, and the third display area DA3. For example, the window 65 may be configured as a single window to cover all upper sides of the first display panel 61a, the second display panel 61b, and the third display panel 61c. To describe this from another perspective, the window 65 may be multi-laminated over the components corresponding to the first display area DA1, the second display area DA2, and the third display area DA3.

Accordingly, the display device 6 may perform the function of displaying multiple images while being configured as a single device.

The display device 6 may further include an adhesive layer 66.

The adhesive layer 66 may be disposed between multiple layers forming the display device 6 and function to bond those layers together.

In an embodiment, the adhesive layer 66 may be disposed between the display panel 61 and the window 65. For example, the adhesive layer 66 may bond the window 65 to the components disposed at locations corresponding to the first display area DA1, the second display area DA2, and the third display area DA3.

In an embodiment, the adhesive layer 66 may simultaneously bond windows 65 to the components corresponding to the first display area DA1, the components corresponding to the second display area DA2, and the components corresponding to the third display area DA3.

The display device 6 may further include a light-blocking member 67.

The light-blocking member 67 may be disposed at one location in the display device 6, and may perform the function of blocking light from passing through unintended areas.

The light-blocking member 67 may include a material that does not transmit light. As an example, the light-blocking member 67 may include carbon black.

In an embodiment, the light-blocking member 67 may be disposed to overlap at least a portion of the periphery of the first display area DA1, the second display area DA2, and the third display area DA3. For example, as shown in FIG. 16, the light-blocking member 67 may be disposed below the window 65 to surround the first display area DA1, the second display area DA2, and the third display area DA3. Accordingly, the light-blocking member 67 may prevent or reduce a light leakage phenomenon occurring around the periphery of the first display panel 61a, the second display panel 61b, and the third display panel 61c.

In an embodiment, the light-blocking member 67 may be disposed to overlap the boundary between the first display area DA1, the second display area DA2, and the boundary between the second display area DA2 and the third display area DA3. For example, as shown in FIG. 16, the light-blocking member 67 may be disposed below the window 65 and positioned corresponding to the boundary between the first display area DA1 and the second display area DA2, and the boundary between the second display area DA2 and the third display area DA3. Accordingly, the light-blocking member 67 may prevent or reduce the problem that light emitted from the display elements of the display element layer DPL disposed in the first display panel 61a penetrates into the second display area DA2, or light emitted from the display elements of the display element layer DPL disposed in the second display panel 61b penetrates into the first display area DA1. The light-blocking member 67 may prevent or reduce the problem that light emitted from the display elements of the display element layer DPL disposed in the second display panel 61b penetrates into the third display area DA3, or light emitted from the display elements of the display element layer DPL disposed in the third display panel 61c penetrates into the second display area DA2. Accordingly, the first display area DA1, the second display area DA2, and the third display area DA3 can display images clearly and distinctly without being disturbed by light emitted from each other.

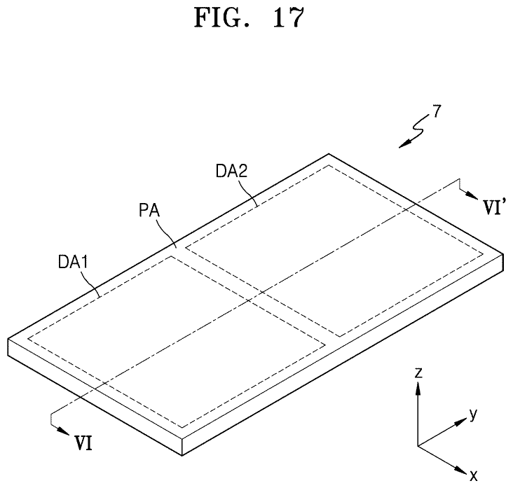

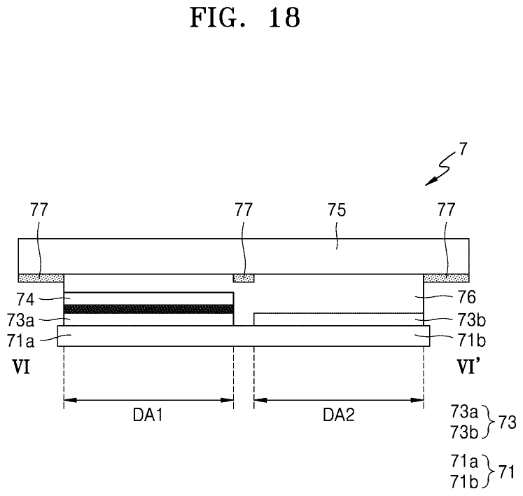

FIG. 17 is a schematic perspective view illustrating a display device according to an embodiment, and FIG. 18 is a schematic cross-sectional view illustrating an example of a cross section taken along line VI-VI′ of FIG. 17.

A display device 7 according to the embodiment may be different from the above-described embodiments in that a display panel corresponding to a first display area DA1 and a display panel corresponding to a second display area DA2 may be a single integral body, and thus, in the following description, for convenience of description, details that are identical to those previously described or that can be readily applied by a person of ordinary skill in the art to which the disclosure pertains may be omitted or briefly described.

The embodiment of the display device 7 may include not only an embodiment in which two display panels may be integral, but also an embodiment in which three or more display panels may be integral. For convenience of description, the following description will focus on the embodiment in which two display panels may be a single integral body.

A display panel 71 may include at least one of the substrate 100, the organic light-emitting diode 200, and the encapsulation member 300 described with reference to FIGS. 1 to 6. For example, the display panel 71 may include all of the substrate 100, the organic light-emitting diode 200, and the encapsulation member 300 described with reference to FIGS. 1 to 6. However, the disclosure is not limited thereto, and the display panel 71 may further include additional components that perform other functions. As an example, the display panel 71 may further include various components such as the light control layer 350 and the functional layer 420 to change a light path or improve light extraction efficiency.

The display panel 71 may be divided into a first display area DA1, a second display area DA2, and a peripheral area PA. For example, the first display area DA1 and the second display area DA2 may be spaced apart from each other so as to be distinguishable. The peripheral area PA may be disposed to surround the first display area DA1 and the second display area DA2.

The display device 7 may provide a selectable image using light emitted from pixels disposed in the first display area DA1 and the second display area DA2. For example, the first display area DA1 and the second display area DA2 may provide different images. As another example, the first display area DA1 and the second display area DA2 may also provide the same image. As another example, the first display area DA1 and the second display area DA2 may also provide images that are continuous with each other.

The display panel 71 may be disposed at positions corresponding to the first display area DA1 and the second display area DA2. For example, the display panel 71 may be integral to cover both the first display area DA1 and the second display area DA2.

To describe this from another perspective, the display panel 71 may include a single substrate, on which pixel layers PXL, encapsulation members 300 sealing the pixel layers PXL, light control layers 350 disposed on the encapsulation members 300, bonding layers 410 disposed on the light control layers 350, and functional layers 420 disposed on the bonding layers 410 are stacked, and these layers, including identical layers, may be formed to be spaced apart from each other. Accordingly, it can be seen that two display parts representing different images are provided on a single substrate.

A first polarizing layer 73a may be disposed on a first display panel 71a, and a second polarizing layer 73b may be disposed on a second display panel 71b.

Each of the first display panel 71a and the second display panel 71b may transmit only light vibrating in the same direction as a polarization axis thereof among light emitted from display elements of a display element layer DPL disposed in the respective display panels 71, and may absorb or reflect light vibrating in other directions.

The first polarizing layer 73a and the second polarizing layer 73b may be formed identical to each other to perform the same function, but are not limited thereto, and may be formed to differ from each other as needed. A polarizing layer 73 may include the first polarizing layer 73a and the second polarizing layer 73b of FIG. 18.

The display device 7 may include a light control member. For example, the display device 7 may include a first light control member 74 disposed in the first display area DA1. For example, the first light control member 74 may be disposed above the first display panel 71a.

The first light control member 74 may include a light-absorbing layer (not shown) and a polymer layer (not shown) as described above. In an optional embodiment, the first light control member 74 may further include a coating layer (not shown).

The first light control member 74 may have a louver structure.

The louver structure may be formed by arranging light-absorbing materials, which are formed to extend to have a length, parallel to each other. For example, it can also be described that the louver structure forms a lattice structure.

The light-absorbing material may include carbon black, but the disclosure is not limited thereto, and any material that appears black or can absorb light may be used as the light-absorbing material.

The function of the louver structure and the method of forming the louver structure are the same as those described with reference to FIGS. 7 to 9, and thus, a detailed description thereof may be omitted below.

The display device 7 may further include a window 75. The window 75 may be disposed on the display panel 71 to cover the first display area DA1 and the second display area DA2.

Here, the term “being disposed on the display panel 71” does not necessarily mean being disposed directly above the display panel 71, but may include a case in which additional components or layers are further disposed between the display panel 71 and the window 75.

In a given embodiment, the window 75 may be provided to cover the first display area DA1 and the second display area DA2. To describe this from another perspective, the window 75 may be multi-laminated on top of the components corresponding to the first display area DA1 and the components corresponding to the second display area DA2.

Accordingly, the display device 7 may perform the function of displaying multiple images while being configured as a single device.

The display device 7 may further include an adhesive layer 76.

The adhesive layer 76 may be disposed between multiple layers forming the display device 7 and function to bond those layers together.

In an embodiment, the adhesive layer 76 may be disposed between the display panel 71 and the window 75. For example, the adhesive layer 76 may bond the window 75 to the components disposed at locations corresponding to the first display area DA1 and the second display area DA2.

In an embodiment, the adhesive layer 76 may simultaneously bond one window 75 to the components corresponding to the first display area DA1 and the components corresponding to the second display area DA2.

The display device 7 may further include a light-blocking member 77.

The light-blocking member 77 may be disposed at one location in the display device 7, and may perform the function of blocking light from passing through unintended areas.

The light-blocking member 77 may include a material that does not transmit light. As an example, the light-blocking member 77 may include carbon black.

In an embodiment, the light-blocking member 77 may be disposed to overlap at least a portion of the periphery of the first display area DA1 and the second display area DA2. For example, as shown in FIG. 18, the light-blocking member 77 may be disposed below the window 75 to surround the first display area DA1 and the second display area DA2. Accordingly, the light-blocking member 77 may prevent or reduce a light leakage phenomenon occurring around the periphery of the first display panel 71a and the second display panel 71b.

In an embodiment, the light-blocking member 77 may be disposed to overlap the boundary between the first display area DA1 and the second display area DA2. For example, as shown in FIG. 18, the light-blocking member 77 may be disposed below the window 75 and positioned corresponding to the boundary between the first display area DA1 and the second display area DA2. Accordingly, the light-blocking member 77 may prevent or reduce the problem that light emitted from the display elements of the display element layer DPL disposed in the first display panel 71a penetrates into the second display area DA2, or light emitted from the display elements of the display element layer DPL disposed in the second display panel 71b penetrates into the first display area DA1. Accordingly, the first display area DA1 and the second display area DA2 can display images clearly and distinctly without being disturbed by light emitted from each other.

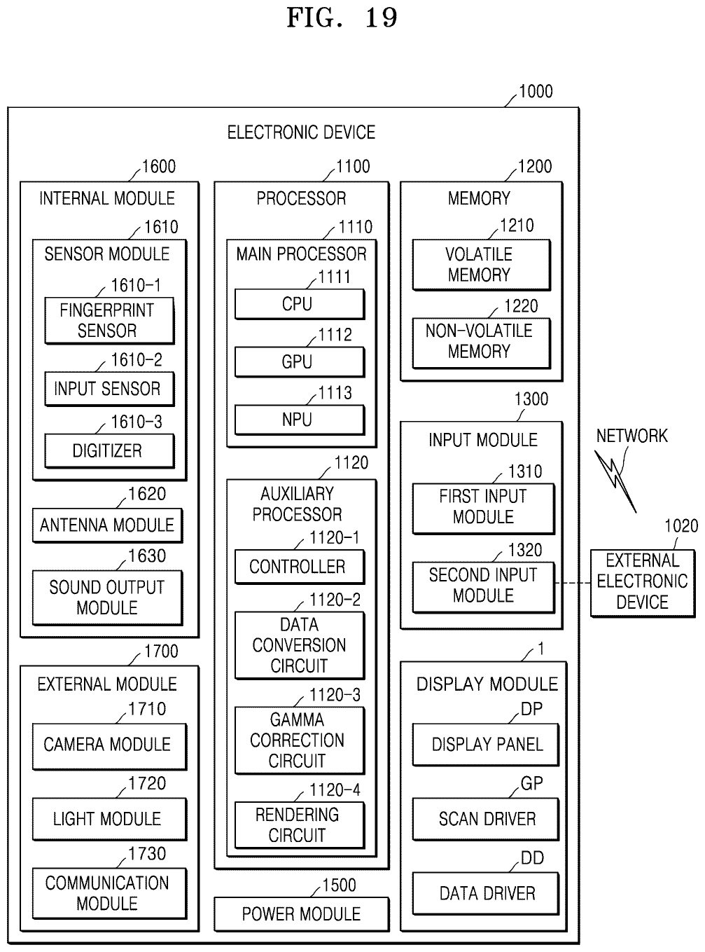

FIG. 19 is a diagram illustrating an example of an electronic device according to embodiments.

Referring to FIG. 19, an electronic device 1000 outputs various pieces of information through a display device 1 in an operating system. In case that a processor 1100 executes an application stored in a memory 1200, the display device 1 provides application information to a user through a display panel DP.

Here, the display device 1 may be one of the display devices 1, 5, 6, and 7 described with reference to FIGS. 1 to 18. However, for convenience of description, the display device 1 will be used as an example in the following description.

The display panel DP may be one of the display panels 51, 61, and 71 described with reference to FIGS. 1 to 18.

The processor 1100 obtains an external input through an input module 1300 or a sensor module 1610 and executes an application corresponding to the external input. For example, in case that the user selects a camera icon displayed on the display panel DP, the processor 1100 obtains a user input through an input sensor 1610-2 and activates a camera module 1710. The processor 1100 transmits image data corresponding to a captured image obtained through the camera module 1710 to the display device 1. The display device 1 may display an image corresponding to the captured image through the display panel DP.

In another example, in case that personal information authentication is executed in the display device 1, a fingerprint sensor 1610-1 may obtain input fingerprint information as input data. The processor 1100 compares input data obtained through the fingerprint sensor 1610-1 with authentication data stored in the memory 1200, and executes an application according to a comparison result. The display device 1 may display information executed according to a logic of the application through the display panel DP.

In another example, in case that a music streaming icon displayed on the display device 1 is selected, the processor 1100 may obtain a user input through the input sensor 1610-2 and activates a music streaming application stored in the memory 1200. In case that a music playback command is input in the music streaming application, the processor 1100 activates a sound output module 1630 to provide sound information corresponding to the music playback command to the user.

In the above, an operation of the electronic device 1000 has been briefly described. Hereinafter, a configuration of the electronic device 1000 will be described in detail. Some of the configurations of the electronic device 1000 to be described below may be integrated and provided as one configuration, or one configuration may be separated into two or more configurations and provided.

Referring to FIG. 19, the electronic device 1000 may communicate with an external electronic device 1020 through a network (for example, a short-range wireless communication network or a long-range wireless communication network). According to an embodiment, the electronic device 1000 may include the processor 1100, the memory 1200, the input module 1300, the display device 1, a power module 1500, an internal module 1600, and an external module 1700. According to an embodiment, in the electronic device 1000, at least one of the above-described components may be omitted, or one or more other components may be added. According to an embodiment, some of the above-described components (for example, the sensor module 1610, an antenna module 1620, or the sound output module 1630) may be integrated into one other component (for example, the display device 1).

The processor 1100 may execute software to control at least one other component (for example, a hardware or software component) of the electronic device 1000 connected to the processor 1100, and perform various data processing or computational operations. According to an embodiment, as at least a portion of the data processing or computational operations, the processor 1100 may store a command or data received from another component (for example, the input module 1300, the sensor module 1610, or a communication module 1730) in a volatile memory 1210 and process the command or the data stored in the volatile memory 1210, and result data may be stored in a non-volatile memory 1220.

The processor 1100 may include a main processor 1110 and an auxiliary processor 1120. The main processor 1110 may include one or more of a central processing unit (CPU) 111-1 or an application processor (AP). The main processor 1110 may further include one or more of a graphic processing unit (GPU) 1110-2, a communication processor (CP), and an image signal processor (ISP). The main processor 1110 may further include a neural processing unit (NPU) 1110-3. The NPU is a processor specialized in processing an artificial intelligence model, which may be generated through machine learning. The artificial intelligence model may include artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more of the above, but is not limited to the above-described example. The artificial intelligence model may include, additionally or by way of example, a software structure in addition to the hardware structure. At least two of the above-described processing units and processors may be implemented as one integrated configuration (for example, a single chip), or each may be implemented as an independent configuration (for example, as a plurality of chips).

The auxiliary processor 1120 may include a controller 1120-1. The controller 1120-1 may include an interface conversion circuit and a timing control circuit. The controller 1120-1 receives an image signal from the main processor 1110, converts a data format of the image signal to correspond to an interface specification with the display device 1, and outputs image data. The controller 1120-1 may output various control signals desirable for driving the display device 1.

The auxiliary processor 1120 may further include the controller 1120-1, a data conversion circuit 1120-2, a gamma correction circuit 1120-3, a rendering circuit 1120-4, and the like within the spirit and the scope of the disclosure. The data conversion circuit 1120-2 may receive image data from the controller 1120-1, compensate the image data to display an image with a desired luminance according to a characteristic of the electronic device 1000, user settings, or the like, or convert the image data for reduction of power consumption, afterimage compensation, or the like within the spirit and the scope of the disclosure. The gamma correction circuit 1120-3 may convert the image data, a gamma reference voltage, or the like so that the image displayed on the electronic device 1000 has a desired gamma characteristic. The rendering circuit 1120-4 may receive the image data from the controller 1120-1 and render the image data in consideration of a pixel arrangement or the like of the display panel DP applied to the electronic device 1000. At least one of the data conversion circuit 1120-2, the gamma correction circuit 1120-3, and the rendering circuit 1120-4 may be integrated into another component (for example, the main processor 1110 or the controller 1120-1). At least one of the data conversion circuit 1120-2, the gamma correction circuit 1120-3, and the rendering circuit 1120-4 may be integrated into a data driver DD to be described later.

The memory 1200 may store various pieces of data used by at least one component (for example, the processor 1100 or the sensor module 1610) of the electronic device 1000, and input data or output data for a command related to the component. The memory 1200 may include at least one of the volatile memory 1210 and the non-volatile memory 1220.

The input module 1300 may receive a command or data to be used by the component (for example, the processor 1100, the sensor module 1610, or the sound output module 1630) of the electronic device 1000 from external sources (for example, a user or the external electronic device 1020) of the electronic device 1000.

The input module 1300 may include a first input module 1310 to which a command or data is input from the user and a second input module 1320 to which a command or data is input from the external electronic device 1020. The first input module 1310 may include a microphone, a mouse, a keyboard, a key (for example, a button), or a pen (for example, a passive pen or an active pen). The second input module 1320 may support a designated protocol that enables connection with the external electronic device 1020 via wired or wireless communication. According to an embodiment, the second input module 1320 may include a high definition multimedia interface (HDMI), a universal serial bus (USB) interface, a secure digital (SD) card interface, or an audio interface. The second input module 1320 may include a connector that enables connection with the external electronic device 1020, such as an HDMI connector, a USB connector, an SD card connector, or an audio connector (for example, a headphone connector).

The display device 1 visually provides information to the user. The display device 1 may include the display panel DP, a scan driver GP, and the data driver DD. The display device 1 may further include a window, a chassis, and a bracket for protecting the display panel DP.

The display panel DP may further include an emission driver. The emission driver outputs an emission control signal to the display panel DP in response to the control signal received from the controller 1120-1. The emission driver may be formed separately from the scan driver GP or may be integrated into the scan driver GP.

The scan driver GP receives a control signal from the controller 1120-1 and outputs scan signals to the display panel DP in response to the control signal. For example, the control signal generated by the controller 1120-1 and transmitted to the scan driver GP may be a scan input signal for controlling the scan driver GP. The scan input signal may be an input signal applied to switching elements included in stages of the scan driver.

The data driver DD receives the control signal from the controller 1120-1, converts image data into analog voltages (for example, data voltages) in response to the control signal, and outputs the data voltages to the display panel DP. For example, the control signal generated by the controller 1120-1 and transmitted to the data driver DD may be a data input signal for controlling the data driver DD.

The data driver DD may be integrated into another component (for example, the controller 1120-1). Functions of the interface conversion circuit and the timing control circuit of the controller 1120-1 described above may be integrated into the data driver DD.

The controller 1120-1 may generate clock signals desirable for driving the scan driver GP. Each of the stages of the scan driver GP may operate based on the clock signal corresponding to each stage.

The scan driver GP may generate the scan signals based on the scan input signal, the clock signal, and scan input voltages. The scan signals may be transmitted to a pixel circuit, and thin-film transistors included in the pixel circuit may be driven based on the scan signals. The scan signals may be delivered to gates included in the pixel circuit.

The display device 1 may further include the emission driver, a voltage generating circuit, and the like within the spirit and the scope of the disclosure. The voltage generating circuit may output various voltages desirable for driving the display panel DP.

The power module 1500 supplies power to components of the electronic device 1000. The power module 1500 may generate gate drive voltages (for example, a gate high voltage and a gate low voltage) desirable for driving the scan driver GP.

For example, the power module 1500 may refer to a power generator, a power supply, or the like within the spirit and the scope of the disclosure. For example, the power module 1500 may include a battery that charges a power supply voltage. The battery may include a non-rechargeable primary cell, and a rechargeable secondary cell or fuel cell.

For example, the power module 1500 may include a power management integrated circuit (PMIC). The PMIC provides optimized power to each of the above-described modules and modules to be described later.

For example, the power module 1500 may include a wireless power transmitting and receiving member electrically connected to the battery. The wireless power transmitting and receiving member may include antenna radiators in a coil form.

The electronic device 1000 may further include the internal module 1600 and the external module 1700. The internal module 1600 may include the sensor module 1610, the antenna module 1620, and the sound output module 1630. The external module 1700 may include the camera module 1710, a light module 1720, and the communication module 1730.

The sensor module 1610 may sense an input by a body of the user or an input by a pen of the first input module 1310, and generate an electrical signal or a data value corresponding to the input. The sensor module 1610 may include at least one of the fingerprint sensor 1610-1, the input sensor 1610-2, and a digitizer 1610-3.

The fingerprint sensor 1610-1 may generate a data value corresponding to a fingerprint of the user. The fingerprint sensor 1610-1 may include one of an optical fingerprint sensor or a capacitive fingerprint sensor.

The input sensor 1610-2 may generate a data value corresponding to coordinate information of the input by the body of the user or the pen. The input sensor 1610-2 generates a data value corresponding to a capacitance change amount by the input. The input sensor 1610-2 may sense an input by the passive pen or transmit and receive data to and from the active pen.

The input sensor 1610-2 may also measure a biometric signal such as blood pressure, hydration levels, or body fat. For example, in case that the user touches a sensor layer or a sensing panel with a body part and does not move during a given time, the input sensor 1610-2 may sense a biometric signal based on changes in an electric field caused by the body part and output information desired by the user to the display device 1.

The digitizer 1610-3 may generate a data value corresponding to coordinate information input by the pen. The digitizer 1610-3 generates an electromagnetic change amount by an input as the data value. The digitizer 1610-3 may sense an input by the passive pen or transmit or receive data to or from the active pen.

At least one of the fingerprint sensor 1610-1, the input sensor 1610-2, and the digitizer 1610-3 may be implemented as a sensor layer formed on the display panel DP through a successive process. The fingerprint sensor 1610-1, the input sensor 1610-2, and the digitizer 1610-3 may be disposed above the display panel DP, and any one of the fingerprint sensor 1610-1, the input sensor 1610-2, and the digitizer 1610-3, for example, the digitizer 1610-3, may be disposed below the display panel DP.

At least two of the fingerprint sensor 1610-1, the input sensor 1610-2, and the digitizer 1610-3 may be formed to be integrated into one sensing panel through the same process. In case that at least two of the fingerprint sensor 1610-1, the input sensor 1610-2, and the digitizer 1610-3 are integrated into one sensing panel, the sensing panel may be disposed between the display panel DP and a window disposed above the display panel DP. According to an embodiment, the sensing panel may be disposed on the window, and a location of the sensing panel is not particularly limited.

At least one of the fingerprint sensor 1610-1, the input sensor 1610-2, and the digitizer 1610-3 may be embedded in the display panel DP. For example, at least one of the fingerprint sensor 1610-1, the input sensor 1610-2, and the digitizer 1610-3 may be simultaneously formed through a process of forming elements (for example, a light-emitting element, a transistor, and the like) included in the display panel DP.

The sensor module 1610 may generate an electrical signal or a data value corresponding to an internal state or an external state of the electronic device 1000. The sensor module 1610 may further include, for example, a gesture sensor, a gyro sensor, a barometric sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 1620 may include one or more antennas for transmitting or receiving a signal or power to or from the outside. According to an embodiment, the communication module 1730 may transmit or receive a signal to or from an external electronic device through the antenna suitable for a communication method. An antenna pattern of the antenna module 1620 may be integrated into one configuration (for example, the display panel DP) of the display device 1, or the input sensor 1610-2.

The sound output module 1630 is a device for outputting an audio signal to the outside of the electronic device 1000 and may include, for example, a speaker used for general purposes such as multimedia playback or recording playback, and a receiver used exclusively for receiving a call. According to an embodiment, the receiver may be integral with or separately from the speaker. A sound output pattern of the sound output module 1630 may be integrated into the display device 1.

The camera module 1710 may capture a still image and a moving image. According to an embodiment, the camera module 1710 may include one or more lenses, an image sensor, or an image signal processor. The camera module 1710 may further include an infrared camera capable of measuring the presence or absence of the user, a location of the user, a gaze of the user, and the like within the spirit and the scope of the disclosure.

The light module 1720 may provide light. The light module 1720 may include a light-emitting diode or a xenon lamp. The light module 1720 may operate in conjunction with the camera module 1710 or may operate independently.

The communication module 1730 may support the establishment of a wired or wireless communication channel between the electronic device 1000 and the external electronic device 1020, and the execution of communication through the established communication channel. The communication module 1730 may include one or all of a wireless communication module such as a cellular communication module, a short-range wireless communication module, or a global navigation satellite system (GNSS) communication module, and a wired communication module such as a local area network (LAN) communication module or a power line communication module. The communication module 1730 may communicate with the external electronic device 1020 through a short-range communication network such as Bluetooth, WiFi direct, or infrared data association (IrDA), or a long-range communication network such as a cellular network, the Internet, or a computer network (for example, a LAN or a wide area network (WAN). The various types of communication modules 1730 described above may be implemented as a single chip or as separate chips.

The input module 1300, the sensor module 1610, and the camera module 1710 may be used in conjunction with the processor 1100 to control an operation of the display device 1.

The processor 1100 outputs a command or data to the display device 1, the sound output module 1630, the camera module 1710, or the light module 1720 based on the input data received from the input module 1300. For example, the processor 1100 may generate image data in response to the input data received through a mouse, an active pen, or the like and output the image data to the display device 1, or generate command data in response to the input data and output the command data to the camera module 1710 or the light module 1720. In case that the input data is not received from the input module 1300 during a given time, the processor 1100 may reduce the power consumption of the electronic device 1000 by switching the operation of the electronic device 1000 to a low-power mode or a sleep mode.

The processor 1100 outputs a command or data to the display device 1, the sound output module 1630, the camera module 1710, or the light module 1720 based on sensing data received from the sensor module 1610. For example, the processor 1100 may compare the authentication data provided by the fingerprint sensor 1610-1 with authentication data stored in the memory 1200, and execute an application according to a comparison result. The processor 1100 may execute the command based on the sensing data sensed by the input sensor 1610-2 or digitizer 1610-3, or output corresponding image data to the display device 1. In case that the sensor module 1610 may include a temperature sensor, the processor 1100 may receive temperature data about a measured temperature from the sensor module 1610 and further perform luminance correction or the like on the image data based on the temperature data.

The processor 1100 may receive measurement data regarding the presence or absence of the user, the location of the user, the gaze of the user, and the like, from the camera module 1710. The processor 1100 may further perform luminance correction or the like on the image data based on the measurement data. For example, after determining the presence or absence of the user through an input from the camera module 1710, the processor 1100 may output image data of which a luminance is corrected through the data conversion circuit 1120-2 or the gamma correction circuit 1120-3 to the display device 1.

Some of the components described above may be connected to each other through a communication method between peripheral devices, such as a bus, a general purpose input/output (GPIO), a serial peripheral interface (SPI), a mobile industry processor interface (MIPI), or an ultra path interconnect (UPI) link, to exchange a signal (for example, a command or data) with each other. The processor 1100 may communicate with the display device 1 through an agreed interface, for example, may use any one of the communication methods described above, and is not limited to the above-described communication methods.

The electronic device 1000 according to various embodiments disclosed in this document may be various types of devices. The electronic device 1000 may include at least one of, for example, a portable communication device (for example, a smartphone), a computer device, a portable multimedia device, a portable medical device, a camera, a wearable device, or a home appliance. The electronic device 1000 according to an embodiment of this document is not limited to the above-described devices.

In an embodiment, the display device 1 may include the display panel DP and the scan driver GP. The controller 1120-1 may generate a scan input signal desirable for driving the scan driver GP. The power module may generate a scan input voltage desirable for driving the scan driver GP under the control of the processor or the controller 1120-1. For example, the scan input voltage may be a gate driving voltage.

The display panel DP may be divided into a display area DA in which the pixel circuit is disposed, and a peripheral area PA around the display area DA. As described above, an area in which images are displayed may be the display area DA, and an area outside the display area DA, in which the images are not displayed, may be the peripheral area PA.

The scan driver GP may be disposed in the peripheral area, and may receive a scan input signal from the controller 1120-1 and receive the scan input voltage from the power module. The scan driver GP may generate or output the scan signal based on the scan input signal and/or the scan input voltage. The scan signal may be transmitted from the scan driver GP to the pixel circuit.

In an embodiment, the scan driver GP may include at least one capacitor. The at least one capacitor may include a first electrode and a second electrode. For example, the first electrode may be a signal line through which at least one of the scan input signal and the scan input voltage is transmitted. For example, the first electrode may be at least a portion of the signal line through which at least one of the scan input signal or the scan input voltage is transmitted. As an example, the signal line may be a wiring through which the scan input voltage is transmitted.

For example, the second electrode may overlap the first electrode. The second electrode may overlap the signal line through which at least one of the scan input signal and the scan input voltage is transmitted. For example, the second electrode may overlap at least a portion of the signal line through which at least one of the scan input signal and the scan input voltage is transmitted.

In an embodiment, the peripheral area PA may include a wiring layout area in which wirings are disposed and a circuit layout area in which at least one transistor is disposed between the display area DA and the wiring layout area. For example, at least one capacitor may be disposed in the wiring layout area.

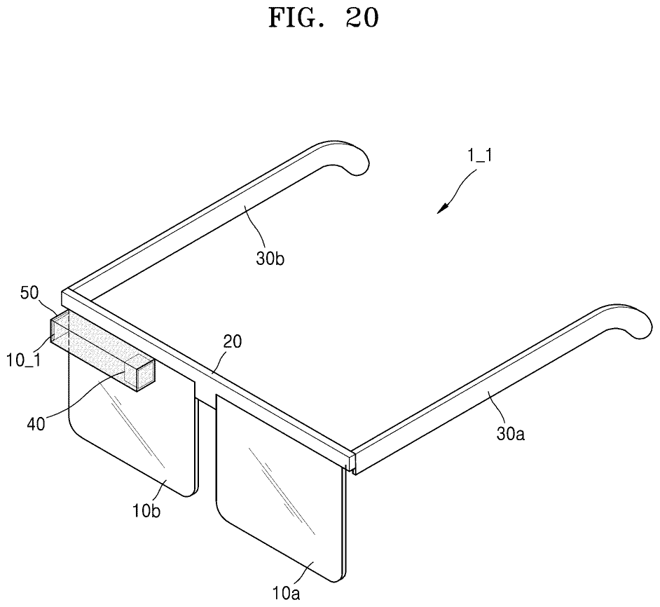

Referring to FIG. 20, the virtual reality device 1_1 according to an embodiment may be a device in a form of glasses. The virtual reality device 1 according to an embodiment may include a display device 1, a left-eye lens 10a, a right-eye lens 10b, a support frame 20, left and right legs 30a and 30b, a reflective member 40, and a display device housing 50.

FIG. 20 illustrates the virtual reality device 1 including the two legs 30a and 30b. However, the disclosure is not limited thereto. The virtual reality device 1 according to an embodiment may be used in a head-mounted display including a head-mounted band that is mounted on a head instead of the legs 30a and 30b. For example, the virtual reality device 1 according to an embodiment may not be limited to the example shown in FIG. 20, and may be applied in various forms and in various electronic devices.

The display device housing 50 may receive the display device 1 and the reflective member 40. An image displayed on the display device 1 may be reflected from the reflective member 40 and provided to a user's right eye through the right-eye lens 10b. Thus, the user may view a virtual reality image displayed on the display device 10 via the right eye.

FIG. 20 illustrates that the display device housing 50 is disposed at a right end of the support frame 20. However, an embodiment of the disclosure is not limited thereto. For example, the display device housing 50 may be disposed at a left end of the support frame 20. The image displayed on the display device 10_1 may be reflected from the reflective member 40 and provided to the user's left eye via the left-eye lens 10a. Thus, the user may view the virtual reality image displayed on the display device 10 via the left eye. As another example, the display device housing 50 may be disposed at each of the left end and the right end of the support frame 20. The user may view the virtual reality image displayed on the display device 10_1 via both the left eye and the right eye.

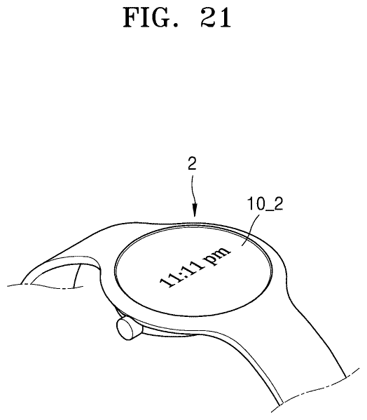

FIG. 21 is an example diagram illustrating a smart device including a display device according to an embodiment.

Referring to FIG. 21, a display device 10_2 according to an embodiment may be applied to a smart watch 2 as one of smart devices. The smartwatch 2 may have a planar shape of the clock display portion that follows the planar shape of the display device 10_2. For example, in case that the display device 10_2 according to an embodiment has a circular or elliptical planar shape, the clock display portion of the smartwatch 2 may have a circular or elliptical planar shape. By way of example, if the display device 10_2 according to an embodiment has a rectangular planar shape, the clock display portion of the smart watch 2 may have a rectangular planar shape. However, embodiments are not limited to these, and the clock display portion of the smart watch 2 may not conform to the planar shape of the display device 10_2.

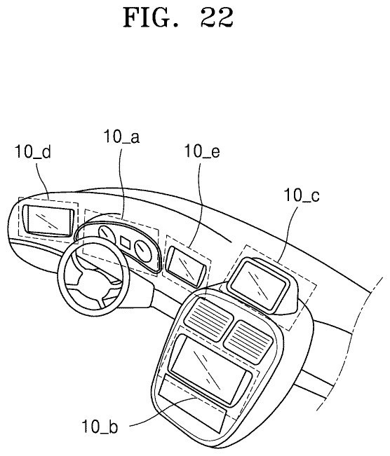

FIG. 22 is an example diagram illustrating a vehicle including a display device according to an embodiment. FIG. 22 illustrates a vehicle in which display devices 10_a, 10_b, 10_c, 10_d, 10_e according to an embodiment are used.

Referring to FIG. 22, the display devices 10_a, 10_b, and 10_c according to an embodiment may be applied to the dashboard of the vehicle, applied to the center fascia of the vehicle, or applied to a CID (Center Information Display) disposed on the dashboard of the vehicle. Further, each of the display devices 10_d and 10_e according to an embodiment may be applied to each room mirror display that replaces each of side-view mirrors of the vehicle.

FIG. 21 is an example diagram illustrating a transparent display device 10_3 including a display device according to an embodiment.

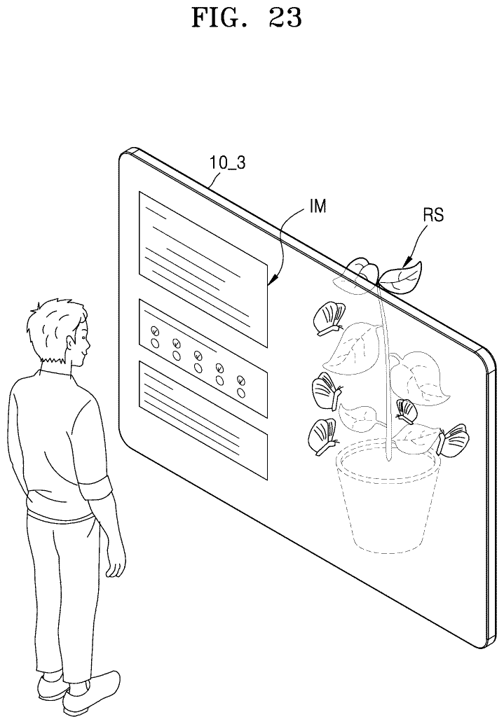

Referring to FIG. 23, a display device 10_3 according to an embodiment may be applied to a transparent display device. The transparent display device may transmit light therethrough while displaying an image IM thereon. Therefore, a user located in front of the transparent display device may not only view the image IM displayed on the display device 10, but also may view an object RS or a background located in the rear of the transparent display device. In case that the display device 10_3 is applied to the transparent display device, the display panel may include a light transmitting portion that transmits light therethrough or may be made of a material that may transmit light therethrough.

The electronic device may be at least one of an organic light-emitting display apparatus, an inorganic light-emitting display apparatus, a quantum dot light-emitting display apparatus, display screens of portable electronic apparatus, such as mobile phones, smartphones, tablet personal computers (PCs), mobile communication terminals, electronic notebooks, electronic books, portable multimedia players (PMPs), navigation devices, and ultra mobile PCs (UMPCs), display screens of televisions, notebooks, monitors, advertisement panels, Internet of things (IoT) devices, a portable communication device a smartphone, a computer device, a portable multimedia device, a portable medical device, a camera, a wearable device, and a home appliance.

As described above, according to an embodiment, a display device with improved visibility and optical characteristics can be provided.

Each of the embodiments described above can be implemented independently, but the structures of the embodiments can also be combined and applied to other embodiments.

The disclosure has been described with reference to the embodiments illustrated in the drawings, but these are only examples. It will be understood by those skilled in the art that various modifications and equivalent other examples may be made. Accordingly, the true technical scope of the disclosure is defined by the technical spirit of the appended claims.

The implementations shown and described herein are illustrative examples of the embodiments and are not intended to otherwise limit the scope of the embodiments in any way. No item or component is essential to the practice of the disclosure unless the component is specifically described as “essential” or “critical.”

The use of the terms “a” and “an” and “the” and similar referents in the context of describing the disclosure (especially in the context of the following claims) are to be construed to cover both the singular and the plural. Further, recitation of ranges of values herein are intended to serve as a shorthand method of referring individually to each separate value falling within the range, unless otherwise indicated herein, and each separate value is incorporated into the specification as if it were individually recited herein. Finally, operations of all methods described herein can be performed in any suitable order unless otherwise indicated herein or otherwise clearly contradicted by context. The disclosure is not necessarily limited to the described order of the operations. The use of any and all examples, or terms provided herein, is intended to better illustrate the embodiments and does not pose a limitation on the scope of the embodiments unless otherwise claimed. It would be apparent to those of ordinary skill in the art that various modifications and changes may be readily made without departing from the scope and spirit of the disclosure.

According to the disclosure, a display device with improved visibility and optical characteristics can be provided.

However, the effect is and the effects of the disclosure are not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope and as defined by the following claims.

What is claimed is:

1. A display device comprising:
a display panel divided into a first display area, a second display area, and a peripheral area surrounding the first display area and the second display area, and including a first display panel disposed at a location corresponding to the first display area and a second display panel disposed at a location corresponding to the second display area; and
a first light control member disposed in the first display area,
wherein the first display panel includes a first substrate and a first pixel defining layer disposed on the first substrate and that defines a pixel, and
the second display panel includes a second substrate and a second pixel defining layer disposed on the second substrate and that defines a pixel, and
the second pixel defining layer is a black pixel defining layer.

2. The display device of claim 1, further comprising a window disposed on the display panel that covers the first display area and the second display area.

3. The display device of claim 1, further comprising a light-blocking member that overlaps at least a portion of a periphery of the first display area and the second display area.

4. The display device of claim 1, further comprising a light-blocking member that overlaps a boundary between the first display panel and the second display panel.

5. The display device of claim 1, wherein the first light control member includes a light-absorbing layer that absorbs at least a portion of light emitted from the first display panel or external light.

6. The display device of claim 1, wherein the first light control member has a louver structure.

7. The display device of claim 6, wherein the louver structure is formed in a direction parallel to a width direction of the display panel.

8. The display device of claim 1, wherein the second pixel defining layer absorbs at least a portion of external light incident on the second display panel.

9. The display device of claim 1, wherein
the second display panel further includes a second wiring disposed between the second substrate and the second pixel defining layer, and
external light incident on the second display panel does not reach the second wiring.

10. The display device of claim 1, wherein a difference between a specular component included_b* (SCI_b*) value of a first reflection color and a specular component included_b* (SCI_b*) value of a second reflection color is at least 0 and not more than 3, the first reflection color exhibited by external light reflected on the first display panel, and the second reflection color exhibited by external light reflected on the second display panel.

11. The display device of claim 1, wherein the first display panel and the second display panel include a plurality of pixels disposed on the first substrate and the second substrate, respectively,
the plurality of pixels include a first pixel, a second pixel, and a third pixel that emit light of different colors, and
at least two of the first pixel, the second pixel, and the third pixel have different areas.

12. The display device of claim 11, wherein the plurality of pixels are disposed such that pixels disposed in a first direction and pixels disposed in a second direction that is rotated by about 90° from the first direction are disposed in a zigzag pattern.

13. The display device of claim 11, wherein the plurality of pixels are disposed diagonally with respect to a width direction of the display panel.

14. The display device of claim 1, wherein the first pixel defining layer is a black pixel defining layer.

15. The display device of claim 1, wherein the display panel further includes a third display area different from the first display area and the second display area, a third display panel disposed at a location corresponding to the third display area, and a third light control member disposed in the third display area.

16. The display device of claim 15, wherein each of the first light control member and the third light control member has a louver structure.

17. The display device of claim 16, wherein the louver structure of the first light control member and the louver structure of the third light control member are formed in different directions.

18. The display device of claim 16, wherein the louver structure of the first light control member and the louver structure of the third light control member are perpendicular to each other.

19. The display device of claim 15, further comprising a light-blocking member that overlaps a boundary surface of the second display panel and a boundary surface of the third display panel.

20. A vehicle comprising:
a controller that generates a scan input signal;
a power module that generates a scan input voltage; and
a display device partitioned into a display area, in which a pixel circuit is disposed, and a peripheral area outside of the display area and including a pad area,
wherein the display device includes:
a display panel divided into a first display area, a second display area, and a peripheral area surrounding the first display area and the second display area, and including a first display panel disposed at a location corresponding to the first display area and a second display panel disposed at a location corresponding to the second display area; and
a first light control member disposed in the first display area,
the first display panel includes a first substrate and a first pixel defining layer disposed on the first substrate and that defines a pixel, and
the second display panel includes a second substrate and a second pixel defining layer disposed on the second substrate and that defines a pixel, wherein the second pixel defining layer is a black pixel defining layer.
